(19) United States
(12) Patent Application Publication
(10) Pub. No.: US 2025/0072299 A1
(43) Pub. Date: Feb. 27, 2025

(54) Electronic Device and Manufacturing Method Thereof

(71) Applicants: TAIWAN SEMICONDUCTOR MANUFACTURING COMPANY, LTD., Hsinchu (TW); NATIONAL TAIWAN UNIVERSITY, TAIPEI (TW)

(72) Inventors: Che-Hao CHANG, Hsinchu City (TW); Jiun-Yun LI, Taipei City (TW); Yu-Cheng LI, Taoyuan City (TW); Yu-Jul WU, Taipei City (TW)

(73) Assignees: TAIWAN SEMICONDUCTOR MANUFACTURING COMPANY, LTD., Hsinchu (TW); NATIONAL TAIWAN UNIVERSITY, TAIPEI (TW)

(21) Appl. No.: 18/454,931

(22) Filed: Aug. 24, 2023

(51) Int. Cl. H10N 60/80; G06N 10/40; H10N 60/01; H10N 60/10

(52) U.S. Cl. CPC H10N 60/80; G06N 10/40; H10N 60/01; H10N 60/11; H10N 60/128

(57) ABSTRACT

An electronic device includes a substrate, a hyperbolic magnet, a pair of depletion gates, a pair of barrier gates and a accumulation gate. The hyperbolic magnet is over the substrate and has a first magnet portion and a second magnet portion separated from each other. The first magnet portion and the second magnet portion have a first convex surface and a second convex surface facing the first convex surface, respectively. The depletion gates are separated from each other and between the first convex surface and the second convex surface over the substrate. The barrier gates are between the depletion gates. The accumulation gate is over the depletion gates and between the barrier gates.

### BACKGROUND

Quantum computing refers to the field of research related to computation systems that use quantum mechanical phenomena to manipulate data. On the roadmap towards building a scalable, silicon-based quantum computer, several milestones have already been achieved. Quantum computing may involve initializing states of N qubits (quantum bits), creating controlled entanglements among them, allowing these states to evolve, and reading out the states of the qubits after the evolution. A qubit is may be a system having two degenerate (i.e., of equal energy) quantum states, with a non-zero probability of being found in either state. Thus, N qubits can define an initial state that is a combination of 2N classical states.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic top view of an electronic device according to one or more embodiments of the present disclosure;

FIGS. 1B, 1C and 1D schematically illustrate cross-section views of the electronic device according to one or more embodiments of the present disclosure;

FIG. 2A illustrates a schematic view of the electronic device of FIG. 1A according to one or more embodiments of the present disclosure;

FIG. 2B illustrates a schematic top view of FIG. 2A;

FIGS. 2C and 2D illustrate schematic top views of magnets occupying different volume in a real space;

FIG. 2E illustrates a diagram of a distance between the magnet portions of the hyperbolic magnet and a gradient of a magnitude of magnetic field generated by the hyperbolic magnet in the direction z;

FIG. 3 illustrates a Bloch sphere presenting a quantum state of the single carrier in the quantum dot region according to one or more embodiments of the present disclosure;

FIGS. 4A and 4B are a schematic top view and a schematic cross-section view illustrating forming a mask layer over a top surface of a substrate according to one or more embodiments of the present disclosure;

FIGS. 5A and 5B are a schematic top view and a schematic cross-section view illustrating forming an alignment mark over the mask layer and the substrate according to one or more embodiments of the present disclosure;

FIGS. 6A and 6B are a schematic top view and a schematic cross-section view illustrating patterning the mask layer to forming openings extending to the top surface of the substrate according to one or more embodiments of the present disclosure;

FIGS. 7A and 7B are a schematic top view and a schematic cross-section view illustrating formation of source/drain regions of the substrate according to one or more embodiments of the present disclosure;

FIGS. 8A and 8B are a schematic top view and a schematic cross-section view illustrating removing of the patterned mask layer according to one or more embodiments of the present disclosure;

FIGS. 9A and 9B are a schematic top view and a schematic cross-section view illustrating depositing a layer stack of a gate dielectric layer and a gate conductive layer over the gate dielectric layer over the substrate according to one or more embodiments of the present disclosure;

FIGS. 10A and 10B are a schematic top view and a schematic cross-section view illustrating formation of gate conductive layers according to one or more embodiments of the present disclosure;

FIGS. 11A and 11B are a schematic top view and a schematic cross-section view illustrating depositing a layer stack of a gate dielectric layer and a gate conductive layer over the depletion gates according to one or more embodiments of the present disclosure;

FIG. 12A and 12B are a schematic top view and a schematic cross-section view illustrating formation of extension gates and accumulation gates according to one or more embodiments of the present disclosure;

FIGS. 13A and 13B are a schematic top view and a schematic cross-section view illustrating depositing a layer stack of a gate dielectric layer and a gate conductive layer over the extension gates and the accumulation gates according to one or more embodiments of the present disclosure;

FIGS. 14A and 14B are a schematic top view and a schematic cross-section view illustrating formation of barrier gates over extension gates and the accumulation gates according to one or more embodiments of the present disclosure;

FIGS. 15A and 15B are a schematic top view and a schematic cross-section view illustrating formation of an isolation dielectric layer over the barrier gates according to one or more embodiments of the present disclosure;

FIGS. 16A and 16B are a schematic top view and a schematic cross-section view illustrating etching the isolation dielectric layer to form a pair of magnet trenches separated from each other according to one or more embodiments of the present disclosure;

FIGS. 17A and 17B are a schematic top view and a schematic cross-section view illustrating formation of a hyperbolic magnet including a pair of magnets according to one or more embodiments of the present disclosure;

FIGS. 18A-19B are schematic top views and schematic cross-section views illustrating formation of vias and contact metal pads connected to the plurality of gates and source/drain regions according to one or more embodiments of the present disclosure;

FIG. 20A, 20B and 20C illustrates a schematic top view and schematic cross-section view of an electronic device according to one or more embodiments of the present disclosure;

FIG. 21 illustrates a schematic top view of an electronic device according to one or more embodiments of the present disclosure; and

FIGS. 22-24 illustrate diagrams used for design electronic device of FIG. 21 according to one or more embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

According to one or more embodiment of the present disclosure, an external uniform magnetic field may be applied to create two spin eigenstates via Zeeman effect for a spin quantum bit (qubit) in a semiconductor quantum dot (QD). An inhomogeneous magnetic field may be used to manipulate spins and process quantum bit information. For a large-scale qubit system, spins in different QDs are addressed individually. Once each spin senses the same magnetic field, all qubits cannot be addressed individually.

In order to maximize the rotation speed of spins to enhance the qubit fidelity, one or more embodiments of the present disclosure provide an electronic device having a magnet adjacent to an accumulation gate of the electronic device to implement one or more qubits with high efficacy. The one or more qubits are configured for the control and readout of an electron or hole spin of a single dopant in a (semiconductor) substrate. The magnet may have a pair of separated magnet portions with convex surfaces used for introducing a magnetic field with large gradient. The magnetic field with large gradient makes the electron or hole spins sense a great effective oscillating magnetic field. The effective oscillating magnetic field may excite electric dipole spin resonance (EDSR), allowing the coherent control of the electron or hole spins, and thus quantum computation. The magnet with the pair of separated magnet portions having convex surfaces can be also used to provide different magnetic field in different position of QDs, and spins in different QDs can be addressed individually. According to one or more embodiments of the present disclosure, it is applicable to large-scale 1D qubit systems, and enhanced addressability of spin qubits (i.e. difference of operation frequencies becomes larger) may reduce qubit crosstalk and improve qubit fidelity.

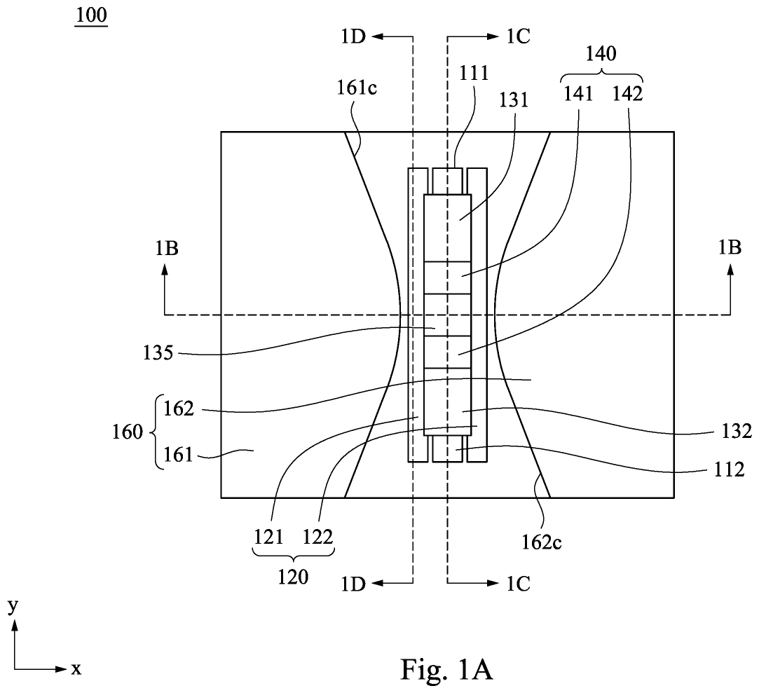

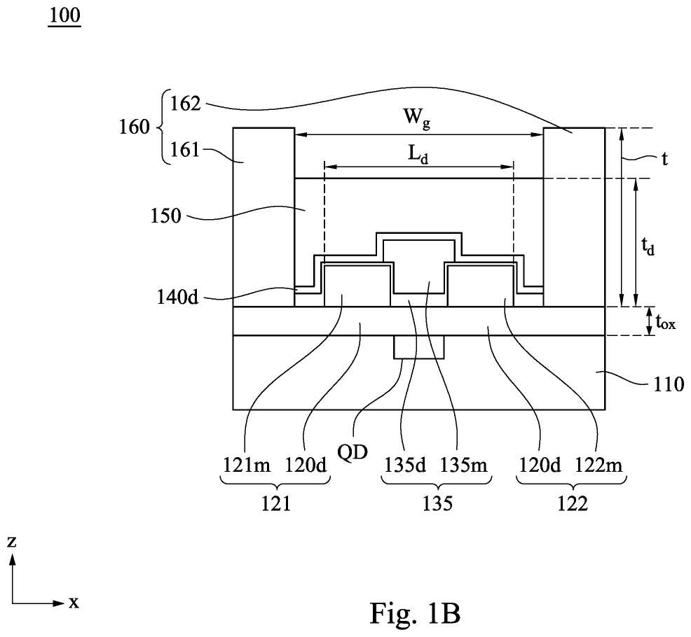

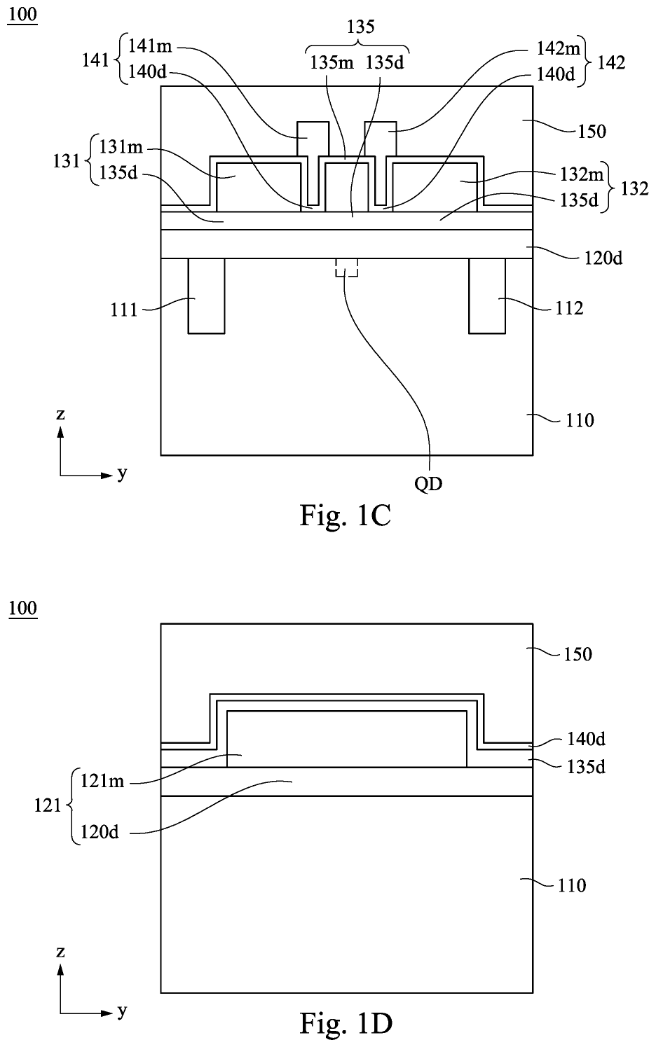

Reference is made to FIGS. 1A, 1B, 1C and 1D. FIG. 1A illustrates a schematic top view of an electronic device 100 according to one or more embodiments of the present disclosure. It is noted that FIG. 1A intends to present configurations of elements and does not limit one or more embodiments of the present disclosure. For the sake of clarity, one or more dielectric layers are not illustrated in FIG. 1A. FIGS. 1B, 1C and 1D schematically illustrate cross-section views of the electronic device 100 according to one or more embodiments of the present disclosure.

As illustrated in FIGS. 1A-1D, in one or more embodiments of the present disclosure, an electronic device 100 includes a substrate 110, a pair of depletion gates 120, an accumulation gate 135, extension gates 131, 132, a pair of barrier gates 140, an isolation dielectric layer 150 and a hyperbolic magnet 160.

In the embodiments as illustrated in FIGS. 1A and 1B, the substrate 110 has a source/drain region 111 and a source/drain region 112 separated from each other in a direction y. The source/drain regions 111 and 112 are doped and have the same semiconductor type. The source/drain regions 111 and 112 may be n-doped regions providing carriers of electrons or p-doped regions providing carriers of holes.

In FIGS. 1A-1D, in one or more embodiments of the present disclosure, a number of gates (e.g., depletion gates 120, accumulation gate 135, extension gates 131, 132 and barrier gates 140) is over a top surface of the substrate 110 between the source/drain regions 111 and 112 to limit a carrier of electron or hole in a quantum dot (QD) region of the substrate 110.

The pair of the depletion gates 120 includes depletion gates 121 and 122 over the substrate 110. As illustrated in FIGS. 1A and 1D, in one or more embodiments of the present disclosure, the depletion gate 121 includes a gate dielectric layer 120d over the substrate 110 and a gate conductive layer 121m over the gate dielectric layer 120d. The depletion gate 122 includes the gate dielectric layer 120d and the gate conductive layer 122m over the gate dielectric layer 120d. The depletion gates 121 and 122 share the same gate dielectric layer 120d. The gate dielectric layer 120d can be regarded as a common dielectric layer and is over a top surface of the substrate 110.

In FIG. 1A, the gate conductive layers 121m and 122m of the depletion gates 121 and 122 extend along direction y and are separated from each other in direction x. Accordingly, the depletion gates 121 and 122 are separated from each other in direction x. As illustrated in the schematic view of FIG. 1A, the source/drain regions 111 and 112 are between the depletion gates 121 and 122.

The accumulation gate 135 is between and over the depletion gates 121 and 122. As illustrated in FIG. 1B, in one or more embodiments of the present disclosure, the accumulation gates 135 includes a gate dielectric layer 135d and a gate conductive layer 135m. The gate dielectric layer 135d is conformally over the gate dielectric layer 120d and the gate conductive layers 121m and 122m of the depletion gates 121 and 122. The gate conductive layer 135m is over the gate dielectric layer 135d and extends between the gate conductive layers 121m and 122m of the depletion gates 121 and 122.

In FIG. 1B, the gate conductive layer 135m of the accumulation gate 135 has a portion over the gate conductive layer 121m of the depletion gate 121, a portion over the gate conductive layer 122m of the depletion gate 122 and a portion extend between the gate conductive layers 121m and 122m. The gate conductive layer 135m and the gate conductive layers 121m, 122m are separated from each other by the gate dielectric layer 135d.

The accumulation gate 135 is level with and between the extension gates 131 and 132. As illustrated in FIGS. 1A and 1C, the accumulation gate 135 and the extension gates 131 and 132 are arranged in the direction y. In one or more embodiments of the present disclosure, the extension gates 131 and 132 are over the depletion gates 121 and 122. The extension gate 131 includes the gate dielectric layer 135d and a gate conductive layer 131m. The extension gate 132 includes the gate dielectric layer 135d and a gate conductive layer 132m. The extension gates 131, 132 and the accumulation gate 135 share the same gate dielectric layer 135d. The common gate dielectric layer 135d extends between the gate conductive layers 131m and 135m and between the gate conductive layers 135m and 132m. The gate conductive layers 121m, 122m, 131m, 132m and 135m are separated from each other by the gate dielectric layer 135d.

The pair of the barrier gates 140 is over the accumulation gate 135, the extension gates 131 and 132. As illustrated in FIGS. 1A and 1C, the barrier gates 140 include a barrier gate 141 and a barrier gate 142. The barrier gate 141 includes a gate dielectric layer 140d and a gate conductive layer 141 over the gate dielectric layer 140d. The barrier gate 142 includes a gate dielectric layer 140d and a gate conductive layer 142 over the gate dielectric layer 140d. The barrier gates 141 and 142 share the same gate dielectric layer 140d over the gate dielectric layer 135d, the gate conductive layers 131m and 132m of the extension gates 131 and 132 and the gate conductive layer 135m of the accumulation gate 135.

In FIG. 1C, the gate conductive layers 141m and 142m of the barrier gates 141 and 142 are separated from each other by the accumulation gate 135. The barrier gates 141 and 142 are at two opposite sides of the accumulation gate 135 in the direction y.

As shown in FIG. 1C, the gate conductive layer 141m of the barrier gate 141 has a portion over the gate conductive layer 131m of the extension gate 131, a portion over the gate conductive layer 135m of the accumulation gate 135 and a portion extend between the gate conductive layers 131m and 135m. The gate conductive layer 142m of the barrier gate 142 has a portion over the gate conductive layer 132m of the extension gate 132, a portion over the gate conductive layer 135m of the accumulation gate 135 and a portion extend between the gate conductive layers 132m and 135m. The gate conductive layers 141m, 142m, 131m, 132m and 135m are separated from each other by the gate dielectric layer 140d.

The isolation dielectric layer 150 is over the pair of the barrier gates 140. In FIG. 1B, the gate dielectric layer 140d of the pair of the barrier gates 140 is covered by the isolation dielectric layer 150. In FIG. 1C, the gate conductive layers 141m and 142m of the barrier gates 141 and 142 are covered by the isolation dielectric layer 150. In FIG. 1D, the gate dielectric layers 135d and 140d are conformally over the gate conductive layer 121m and the gate dielectric layer 120d of the depletion gate 120 in order, and the isolation dielectric layer 150 is further over the gate dielectric layers 135d and 140d.

As shown in FIG. 1A, the extension gates 131, 132, the barrier gates 141, 142 and the accumulation gate 135 are formed over and between the pair of the depletion gates 120 including depletion gates 121 and 122. In one or more embodiments of the present disclosure, the hyperbolic magnet 160 includes magnet portion 161 and magnet portion 162 separated from each other by the pair of the depletion gates 120 in direction x. The depletion gates 120 are between the magnet portion 161 and the magnet portion 162 of the hyperbolic magnet 160. The magnet portions 161 and 162 of the hyperbolic magnet 160 are over the gate dielectric layer 120d of the depletion gates 121 and 122.

In one or more embodiments of the present disclosure, the magnet portions 161 and 162 extend from a top surface of the gate dielectric layer 120d and protrude from a top surface of the isolation dielectric layer 150. As shown in FIG. 1B, the isolation dielectric layer 150 has a thickness ta from the top surface of the gate dielectric layer 120d to a top surface of the isolation dielectric layer 150 in the direction z. Each of the magnet portions 161 and 162 has a thickness t in the direction y, wherein the thickness t of each of the magnet portions 161 and 162 is greater than the thickness ta of the isolation dielectric layer 150. Top surfaces of the magnet portions 161 and 162 are higher than the top surface of the isolation dielectric layer 150. Bottom surfaces of the magnet portions 161 and 162 are level with the top surface of the gate dielectric layer 120d and bottom surfaces of the gate dielectric layer 135d and the gate conductive layers 121m and 122m. The bottom surfaces of the magnet portions 161 and 162 are lower than top surfaces of the depletion gates 121, 122, a bottom surface of the gate dielectric layer 135d of the accumulation gate 135 and the isolation dielectric layer 150.

As shown in FIG. 1B, the isolation dielectric layer 150 extends between the magnet portions 161 and 162 of the hyperbolic magnet 160. In one or more embodiments of the present disclosure, the gate dielectric layer 135d, the gate dielectric layer 140d and the isolation dielectric layer 150 are directly connected between the magnet portions 161 and 162 of the hyperbolic magnet 160.

Reference is made to FIG. 1A. In one or more embodiments of the present disclosure, the magnet portion 161 has a convex surface 161c being convex towards the direction x, the magnet portion 162 has a convex surface 162c being convex towards the negative direction x, and the convex surfaces 161c and 162c face to each other. In the schematic top view of FIG. 1A, the convex surfaces 161c and 162c are two convex surfaces forming a hyperbola profile at the top view of FIG. 1A, so as to generate a magnet field with a local gradient. The convex surface 161c is symmetric to the convex surface 162c. The isolation dielectric layer 150 extends between the convex surface 161c of the first magnet portion 161 and the convex surface 162c of the second magnet portion 162. The accumulation gate 135 and the quantum dot region QD are located at a focus point of the hyperbola formed by the convex surfaces 161c and 162c.

According to one or more embodiments of the present disclosure, a single carrier of the electronic device 100 can be limited in the quantum dot region QD under the accumulation gate 135 by the depletion gates 121, 122, the barrier gates 141, 142 and the accumulation gate 135. The single carrier is, for example, an electron or a hole. The depletion gates 121, 122, the barrier gates 141, 142 and the accumulation gate 135 can have different energy levels for the single carrier of the electronic device 100 by applying different voltages. For the single carrier of the electronic device 100, the depletion gates 121, 122 and the barrier gates 141, 142 can the regarded as energy barriers, the accumulation gate 135 can be regarded as an energy ground, and the single carrier can be bound at the location, i.e., the quantum dot region QD, of the substrate 110 corresponding to the energy ground.

In one or more embodiments, as examples but not limit to the present disclosure, a single carrier can be provided by the source/drain region 111 of the substrate 110. The single carrier is then guided and flows towards the accumulation gate 135 through the extension gates 131 overlapping the source/drain region 111. When the single carrier approaches the quantum dot regions QD under the accumulation gate 135, an energy level of the barrier gate 141 near the extension gate 131 is reduced to receive the single carrier into the quantum dot regions QD. After the single carrier is moved to the quantum dot region QD, the energy level of the barrier gate 141 is increased to bind the single carrier.

Once the single carrier of the electronic device 100 is bound in the quantum dot region QD under the accumulation gate 135, the single carrier can sense magnetic field generated by the pair of magnet portions 161 and 162 of the hyperbolic magnet 160, and the degenerated electron/hole spin eigenstates (e.g., spin-up and spin-down state) for the single carrier split and have different energies. Furthermore, by applying a AC voltage difference between the depletion gates 121 and 122, the single carrier bound in the quantum region can oscillate under the magnetic field generated by the magnet portions 161 and 162 along direction x in which the depletion gates 121 and 122 are separated from each other. Therefore, the single carrier can be effectively sense an effective AC magnetic field used for spin manipulation of the single carrier. The z-directional magnetic field generated by the magnet portions 161 and 162 has a large gradient along direction x to increase quantum computation speed and improve qubit fidelity for the single carrier of the electronic device 100.

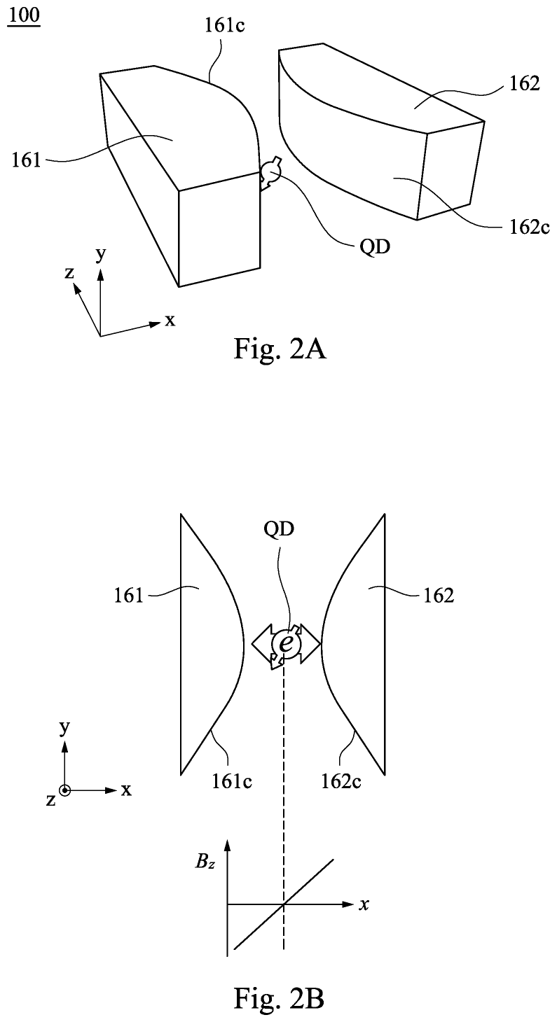

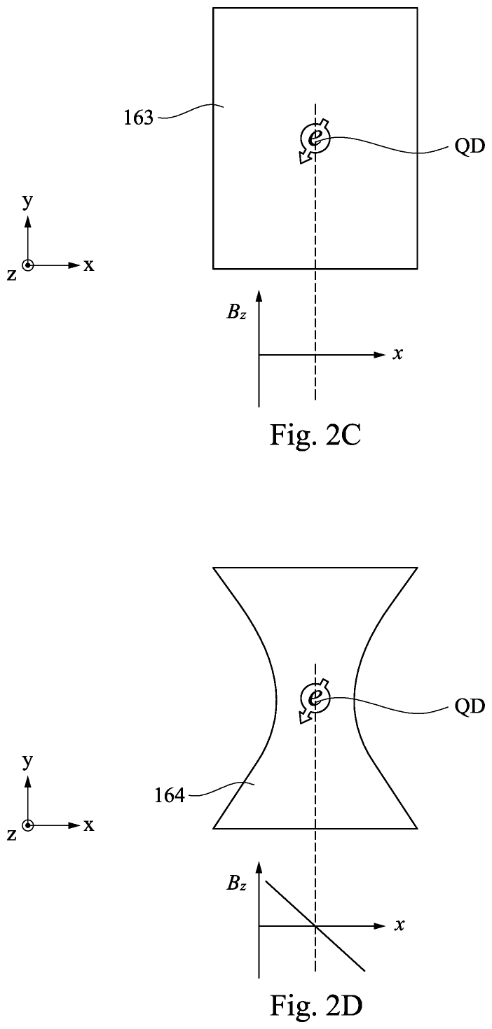

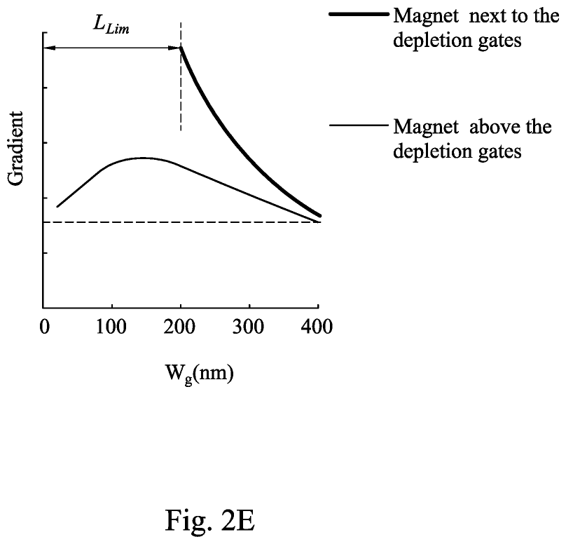

Reference is made to FIGS. 2A-2E to illustrate the magnetic field generated by the pair of magnet portions 161 and 162 of the hyperbolic magnet 160.

FIG. 2A illustrates a schematic view of the electronic device 100, wherein the single carrier is bound in the quantum dot region QD between the convex surfaces 161c and 162c of the magnet portions 161 and 162. For the sake of clarity, the substrate 110, the isolation dielectric layer 150 and a plurality of gates are not shown in FIG. 2A, and FIG. 2A schematically illustrates the single carrier in the quantum dot region QD and the magnet portions 161 and 162.

FIG. 2B illustrates a schematic top view of FIG. 2A, wherein the position along a line across the quantum dot region QD versus the magnitude Bz of the z-directional magnetic field generated by the magnet portions 161 and 162 are presented in a diagram under the schematic view, and the magnitude Bz is proportional to positions along the positive direction x.

FIGS. 2C and FIG. 2D illustrate how to design the magnet portions 161 and 162. FIG. 2C illustrates a schematic top view of a magnet 163 occupying a cube in the real space. The diagram under the schematic top view of the magnet 163 in FIG. 2C presents that the magnitude Bz of the z-directional magnetic field generated by the magnet 163 is a constant value in positions along the direction x for the single carrier in the imaginary quantum dot region QD inside the magnet 163. FIG. 2D illustrates a magnet 164 having a solid shape with two concave surfaces complementary to the magnet portions 161 and 162. The diagram under the schematic top view of the magnet 164 in FIG. 2D presents that the magnitude Bz of the z-directional magnetic field generated by the magnet 164 along direction z is inversely proportional to positions in the direction x for the single carrier in the imaginary quantum dot region QD inside the magnet 164.

Therefore, based on the magnets 163 and 164, the magnet portions 161 and 162 of the pair of the magnet 160 can be provided to generate a magnet field having a z-directional magnet field component with a large gradient across the quantum dot region QD along the direction x, and the magnitude Bz of the z-directional magnetic field generated by the magnets portions 161 and 162 of the pair of the magnet 160 is proportional to positions along the positive direction x.

FIG. 2E illustrates a diagram of the shortest distance W_{g} between the magnet portions 161 and 162 of the hyperbolic magnet 160 (presented in the horizontal axis) versus a gradient of a magnitude of a z-directional magnetic field generated by the hyperbolic magnet 160 along the direction x and sensed by the single carrier bound in the quantum dot region QD (presented in the vertical axis). The thick line presents the gradient of the magnitude of magnetic field generated by the hyperbolic magnet 160 next to the depletion gates 121 and 122. The thin line presents the gradient of a magnitude of an imaginary magnetic field generated by the magnet portions 161 and 162 disposed above the depletion gates 121 and 122. The dash line in the diagram presents a lowest value of the thin line. It is noted that since the depletion gates 121 and 122 are between the magnet portions 161 and 162 of the hyperbolic magnet 160, a length L_{Lim} limits the distance W_{g} between the magnet portions 161 and 162, wherein the length L_{Lim} is determined by the length L_{d} of the pair of the depletion gates 121 and 122.

For the thick line, as illustrated in FIG. 2E, the less the distance W_{g} between the magnet portions 161 and 162 of the hyperbolic magnet 160 is, the greater the gradient of a magnitude of z-directional magnetic field generated by the hyperbolic magnet 160 and sensed by the single carrier bound in the quantum dot region QD. For the thin line, the less the distance W_{g}, the less gradient.

Reference is made to FIG. 1B. FIG. 1B illustrates the cross-section view along a line across the quantum dot regions QD in direction x. As shown in FIG. 1B, the convex surfaces 161c and 162c of the magnet portions 161 and 162 have the shortest distance W_{g} in direction x. The pair of depletion gates 120 including the depletion gates 121 and 122 have a length L_{d} in the direction x. The length La is equal to or less than the distance W_{g}. In one or more embodiments of the present disclosure, as examples and not limited the present disclosure, the coordinates of the convex surfaces 161c and 162c in real space can be presented in the following formula:

Ax²−By²=W_{g}²

wherein the position of the quantum dot regions QD is selected as an original point and coefficients a and b are selected based on the design magnitude of the magnetic field. In some embodiments of the present disclosure, the coefficient A is greater than the coefficient B so that the hyperbola profile extends along the direction y to accommodate more quantum dot regions in the direction y. In some embodiments of the present disclosure, the coefficient A can be 4 and the coefficient B can be 1.

In one or more embodiments of the present disclosure, the length L_{d} of the pair of the depletion gates 120 is equal to or less than 200 nm, and the distance W_{g} is equal to or greater than the length L_{d}. In one or more embodiments of the present disclosure, the distance W_{g} is in a range between 200 nm and 400 nm.

In one or more embodiments of the present disclosure, the gate dielectric layer 120d has a thickness tₒₓ less than 20 nm in direction z.

In one or more embodiments of the present disclosure, the substrate 110 may include silicon (Si). Alternatively, the substrate 110 may include germanium (Ge), silicon germanium, gallium arsenide (GaAs), or other appropriate semiconductor materials. In some alternative embodiments, the substrate 110 may include an epitaxial layer with or without dopants. Furthermore, the substrate 110 may include a semiconductor-on-insulator (SOI) structure having a buried dielectric layer therein. The buried dielectric layer may be, for example, a buried oxide (BOX) layer. The SOI structure may be formed by a method referred to as separation by implantation of oxygen technology, wafer bonding, selective epitaxial growth (SEG), or other appropriate method.

In one or more embodiments of the present disclosure, the gate dielectric layers 120d, 135d and 140d may include LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. The gate dielectric layers 120d, 135d and 140d is deposited by suitable techniques, such as ALD, CVD, PVD, thermal oxidation, combinations thereof, or other suitable techniques.

In one or more embodiments of the present disclosure, the gate conductive layers 121m, 122m, 131m, 132m, 135m, 141m and 142m may include W, Ti, TiAIC, Al, TiAl, TaN, TaAIC, TIN, TiC, Co, TaC, Al, TiAl, HfTi, TiSi, TaSi, TiAIC, combinations thereof, or the like. The gate conductive layers 121m, 122m, 131m, 132m, 135m, 141m and 142m may be formed by chemical vapor deposition (CVD), physical vapor deposition (PVD) including sputtering, atomic layer deposition (ALD) or other suitable method.

In one or more embodiments of the present disclosure, the isolation dielectric layer 150 may include silicon dioxide, silicon nitride, or other suitable material. Alternatively, the isolation dielectric layer 150 can be a high-κ dielectric layer having a dielectric constant (κ) higher than the dielectric constant of SiO₂, i.e. κ>3.9. The isolation dielectric layer 150 may include LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. The isolation dielectric layer 150 is deposited by suitable techniques, such as ALD, CVD. PVD, thermal oxidation, combinations thereof, or other suitable techniques.

In one or more embodiments of the present disclosure, the magnet portions 161 and 162 may include cobalt or other suitable ferromagnetic metals.

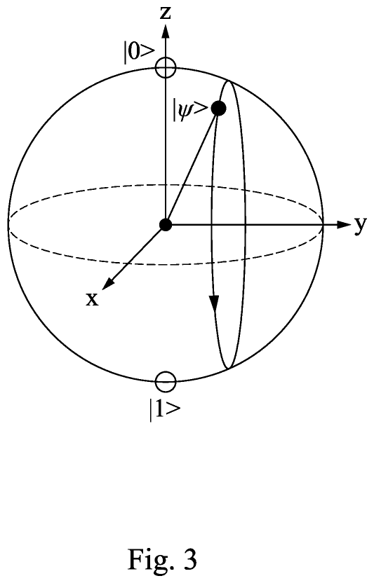

Reference is made to FIG. 3. FIG. 3 illustrates a Bloch sphere presenting a quantum state |Ψ> of the single carrier (e.g., an electron spin state or a hole spin) in the quantum dot region QD, wherein the single carrier bound in the quantum dot region QD and having the quantum state |Ψ> can be used as a spin qubit.

When a DC magnetic field BDC is applied to the quantum dot region QD, the degenerated electron/hole spin eigenstates (e.g., spin-up and spin-down state) of the carrier bound in the quantum dot region QD split and have energy levels. The splitting eigenstates f the carrier bound in the quantum dot region QD are presented as an eigenstate |0> and an eigenstate |1> on a Bloch sphere as illustrated in FIG. 3. The quantum state |Ψ> of the single electron/hole limited in the quantum dot region QD can be presented as following formula: |Ψ>=cos θ|0>+sinθ e^{iφ}|1>.

The quantum state |Ψ> of the single electron/hole limited in the quantum dot region QD can be presented as a combination of the eigenstate |0> and the eigenstate |1>. Therefore, the quantum state |Ψ> of the single electron/hole limited in the quantum dot region QD can be presented as a point over the Bloch sphere of FIG. 3. It is noted that directions x, y and z presented in the Bloch sphere in FIG. 3 are not the direction in the real space and the angles θ and φ are imaginary angles used to present quantum state |Ψ> on the Bloch sphere.

An energy difference ΔE between the eigenstate |0> and the eigenstate |1> is related to a DC magnetic field B_{DC}, which is provided by the hyperbolic magnet 160. After the quantum dot region QD applied by the DC magnetic field B_{DC} and has the splitting eigenstate |0> and the eigenstate |1>, and an AC magnetic field B_{AC} with suitable frequency may further apply to the quantum dot region QD to flip the quantum state |Ψ>. Spin of the quantum state |Ψ> flips when the frequency of the AC magnetic field BAC matches an intrinsic Rabi frequency of the quantum state |Ψ>. In other words, when a different DC magnetic field B_{DC} applies to the quantum dot region QD, the quantum state |Ψ> of the quantum dot region QD can be controlled by applying a further AC magnetic field B_{AC} with suitable frequency matching the Rabi frequency of the quantum state |Ψ> of the single carrier bound in the quantum dot region QD.

In one or more embodiments of the present disclosure, the AC magnetic field B_{AC} is induced by providing AC voltage difference between the gate conductive layers 121m and 122m of depletion gates 121 and 122, and the single carrier bound in the quantum dot region QD oscillates under the DC magnetic field B_{DC} with large gradient would effectively sense the AC magnetic field B_{AC}, and the frequency of the AC magnetic field B_{AC} is basically the same as a frequency of the AC voltage difference.

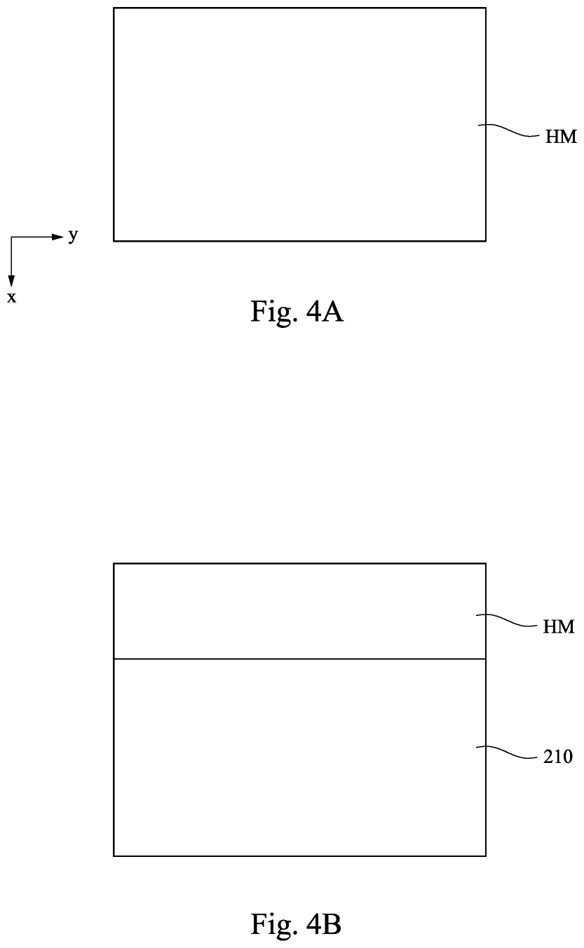

Reference is made to FIGS. 4A-19B to illustrate an electronic device 200 and formation of the electronic device 200 according to one or more embodiments of the present disclosure. In one or more embodiments of the present disclosure, the electronic device 200 may include a plurality of quantum dot regions to bind a plurality of carrier spins independently. The electronic device 200 can be integrated in a large-scale qubit system.

Reference is made to FIGS. 4A and 4B. FIGS. 4A and 4B are a schematic top view and a schematic cross-section view illustrating forming a mask layer HM (may be a hard mask layer HM) over a top surface of a substrate 210, wherein FIG. 4B is a cross-section view of FIG. 4A.

In some embodiments of the present disclosure, the mask layer HM includes nitride. For example, the mask layer HM is made of silicon nitride (SiN). However, other materials, such as SiON, silicon carbide, or combinations thereof, may also be used. The mask layer HM may be formed by a process such as chemical vapor deposition (CVD), plasma enhanced chemical vapor deposition (PECVD), or low pressure chemical vapor deposition (LPCVD). Alternatively, the mask layer HM may be made of a silicon oxide and then converted to SiN by nitridation.

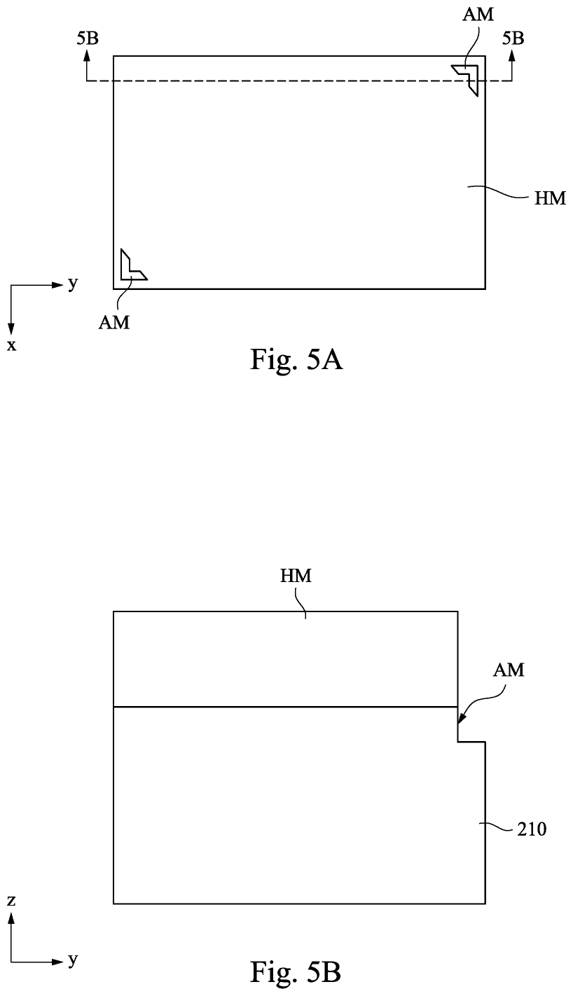

Reference is made to FIGS. 5A and 5B. FIGS. 5A and FIG. 5B are a schematic top view and a schematic cross-section view illustrating forming an alignment mark AM over the mask layer HM and the substrate 210 according to one or more embodiments of the present disclosure.

As shown in FIGS. 5A and 5B, the alignment mark AM can be formed by etching the mask layer HM and the substrate 210, and the alignment mark AM can be an opening extending through the mask layer HM and into the substrate 210. In FIG. 5A, two alignment marks AM are formed over the mask layer HM and the substrate 210.

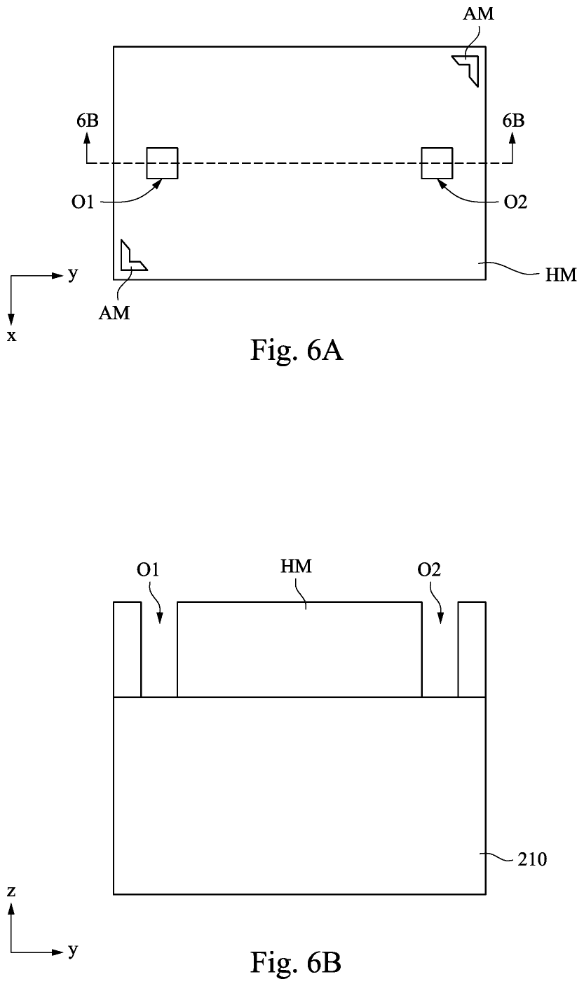

Reference is made to FIGS. 6A and 6B. FIG. 6A and FIG. 6B are a schematic top view and a schematic cross-section view illustrating patterning the mask layer HM to forming openings O1 and 02 extending to the top surface of the substrate 210 according to one or more embodiments of the present disclosure. In one or more embodiments of the present disclosure, after the mask layer HM is formed over the substrate 210, the mask layer HM in FIGS. 5A and 5B is then patterned by a lithography technique.

For example, a photoresist layer can be formed over the structure in FIGS. 5A and 5B, and the photoresist layer is exposed and then developed to form a patterned photoresist layer, which leaves exposed a portion of the mask layer HM. The mask layer HM is then etched using a reactive ion etch (RIE) and/or other suitable process, and the patterned photoresist layer is used as an etch mask for etching the mask layer HM. After the etching process, a patterned mask layer HM having openings 01 and 02 is formed over the substrate 210, and the patterned photoresist layer is removed. In some embodiments of the present disclosure, the patterned photoresist layer may be removed using a process such as ashing, etching, or the like. The openings O1 and O2 of the mask layer HM respectively expose portions of the substrate 210 to define source/drain regions of the substrate 210.

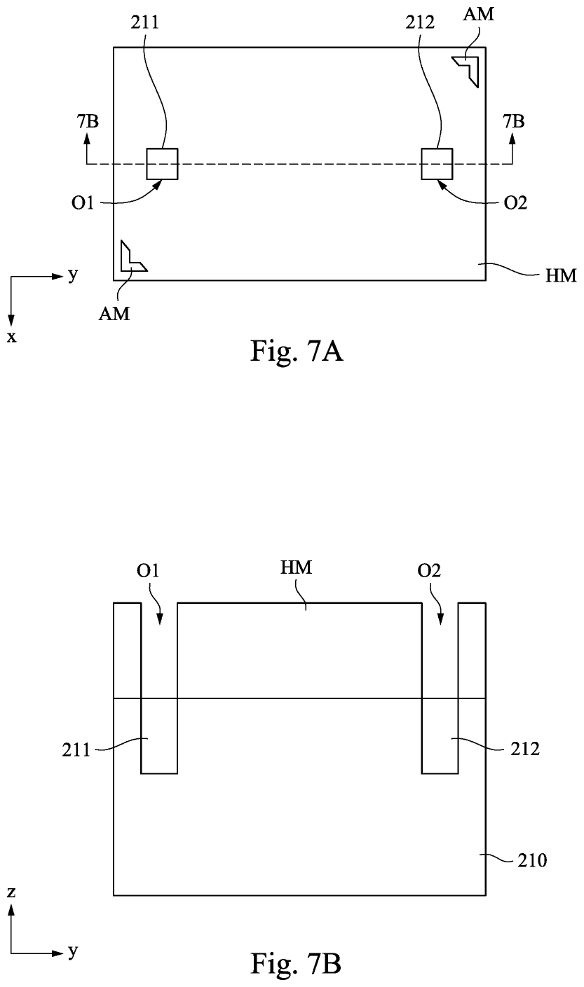

Reference is made to FIGS. 7A and 7B. FIGS. 7A and 7B are a schematic top view and a schematic cross-section view illustrating formation of source/drain regions 211 and 212 of the substrate according to one or more embodiments of the present disclosure.

As illustrated in FIGS. 7A and 7B, an implantation process (e.g., ion implantation process) is performed to introduce impurities into the substrate 210 through the openings O1 and O2 to form source/drain regions 211 and 212 separated from each other in direction x, and the patterned mask layer HM may act as a mask to substantially prevent the impurities from being implanted into other regions of the substrate 210. The impurities may be n-type impurities or p-type impurities. The n-type impurities may be phosphorus, arsenic, or the like, and the p-type impurities may be boron, BF₂, or the like.

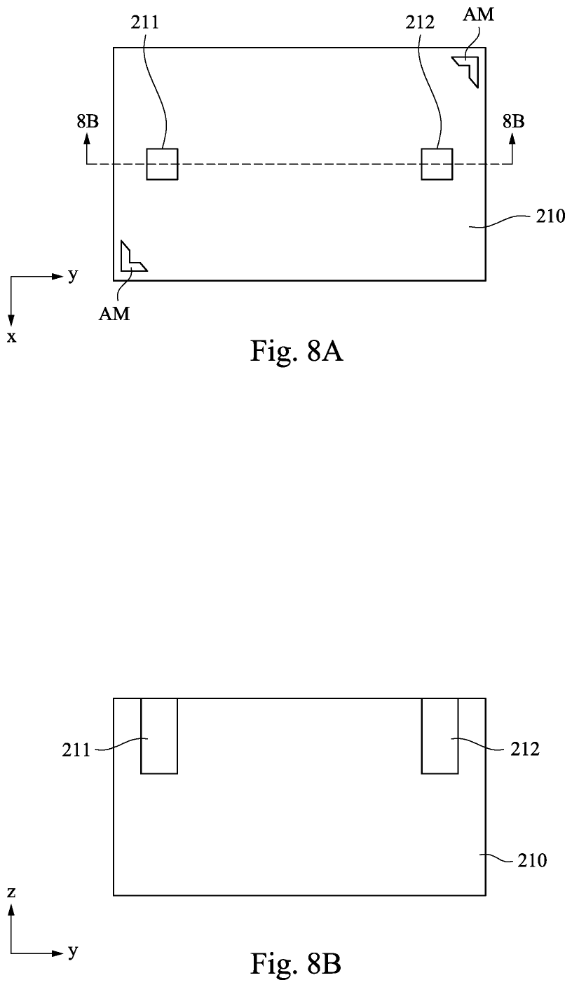

Subsequently, the patterned mask layer HM is removed. Reference is made to FIGS. 8A and 8B. FIG. 8A and FIG. 8B are a schematic top view and a schematic cross-section view illustrating removing of the patterned mask layer HM according to one or more embodiments of the present disclosure.

In one or more embodiments of the present disclosure, as illustrated in FIGS. 8A and 8B, the patterned mask layer HM may be removed using a process such as wet etching, or the like. After the removal process of the patterned mask layer HM, the substrate 210 with the source/drain regions 211 and 212 is exposed. After the patterned mask layer HM is removed, one or more annealing processes may be performed to activate the source/drain regions 211 and 212. The annealing processes include rapid thermal annealing (RTA) and/or laser annealing processes. The annealing processes may repair implant damage from the impurities on the bottom and sidewalls of the source/drain regions 211 and 212.

In one or more embodiments of the present disclosure, after the source/drain regions 211 and 212 of the substrate 210 are formed, a device isolation process can be further performed on the structure as illustrated in FIGS. 8A and 8B. For example, in one or more embodiments of the present disclosure, an isolation layer is formed over the substrate 210. For the sake of clarity, the device isolation process and the isolation layer are not illustrated in figures. In one or more embodiments of the present disclosure, the isolation layer may include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The isolation layer may be deposited by a PECVD process or other suitable deposition technique. Then, an opening is formed in the isolation layer over the substrate 210 to define an active region in the substrate 210. In some embodiments of the present disclosure, the opening is formed using a combination of photolithography and etching process. In some embodiments of the present disclosure, the etching process is a wet etching process. The opening of the isolation layer exposes a portion of the substrate 210 and the source/drain regions 211 and 212, and the exposed portion of the substrate 210 is defined as the active region of the substrate. The top view of the active region of the substrate 210 may be circular, elliptical, rectangular, square, or some other shapes with or without rounded corners.

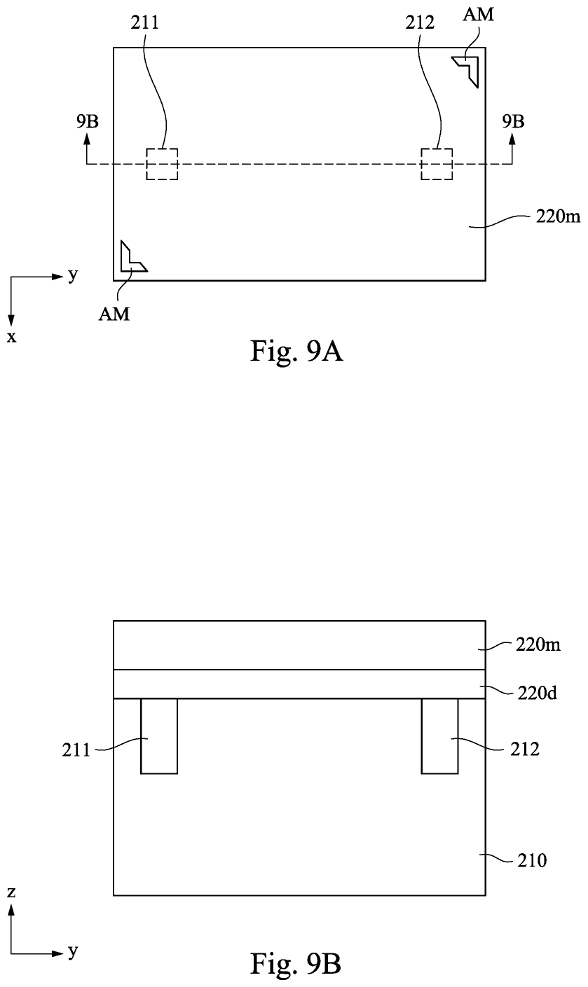

Reference is made to FIGS. 9A and 9B. FIGS. 9A and 9B are a schematic top view and a schematic cross-section view illustrating depositing a layer stack of a gate dielectric layer 220d and a conductive layer 220m over the substrate 210 according to one or more embodiments of the present disclosure. As shown in FIGS. 9A and 9B, the gate dielectric layer 220d is deposited over a top surface the substrate 210, and the conductive layer 220m is deposited over the gate dielectric layer 220d.

In one or more embodiments of the present disclosure, the gate dielectric layer 220d may include Al₂O₃. The source/drain regions 211 and 212 are covered by the gate dielectric layer 220d. In one or more embodiments of the present disclosure, the gate dielectric layer 220d is deposited by suitable techniques, such as ALD, CVD, PVD, thermal oxidation, combinations thereof, or other suitable techniques.

The conductive layer 220m is then formed over the gate dielectric layer 220d. In one or more embodiments of the present disclosure, the conductive layer 220m includes one or more layers of conductive material, e.g., metal material. The conductive layer 220m may be formed by chemical vapor deposition (CVD), physical vapor deposition (PVD) including sputtering, atomic layer deposition (ALD) or other suitable method.

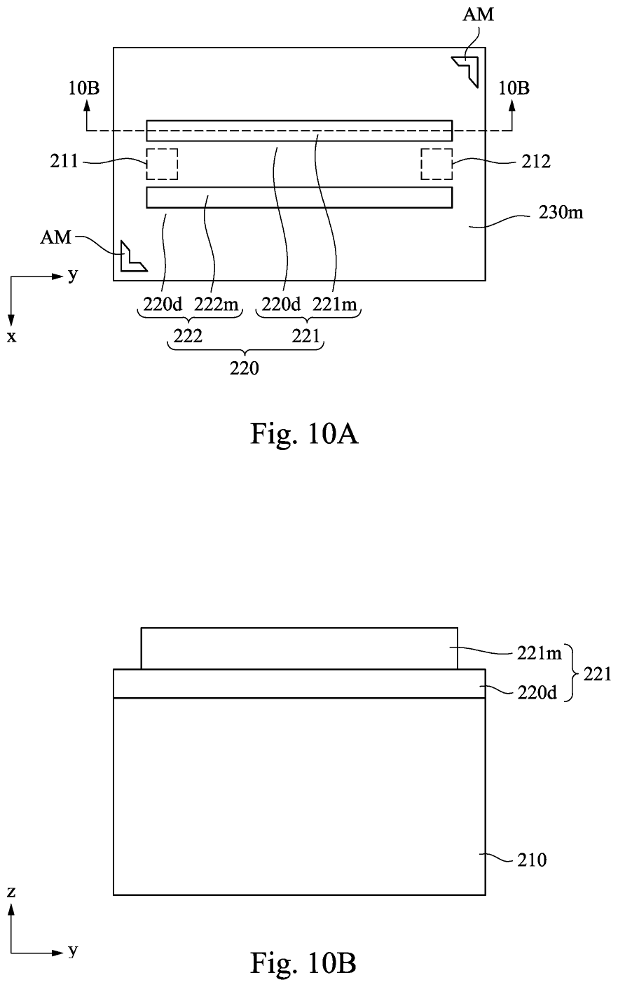

Reference is made to FIGS. 10A and 10B. FIG. 10A and 10B are a schematic top view and a schematic cross-section view illustrating formation of gate conductive layers 221m and 222m according to one or more embodiments of the present disclosure.

As illustrated in FIGS. 10A and 10B, the conductive layer 220m in FIGS. 9A and 9B is patterned to form gate conductive layers 221m and 222m, and a pair of depletion gates 220 separated from each other in the direction x are formed. In one or more embodiments of the present disclosure, the patterning of the conductive layer 220m may be formed using a combination of photolithography for definition of the gate conductive layers 221m and 222m and etching process, for example, reactive ion etch (RIE) process, for forming the gate conductive layers 221m and 222m. In FIGS. 10A and 10B, the gate conductive layers 221m and 222m have lengths basically equal to a distance between the source/drain regions 211 and 212 in the direction y.

Accordingly, in FIGS. 10A and 10B, the pair of the depletion gates 220 including depletion gates 221 and 222 is formed. The depletion gate 221 includes the gate dielectric layer 220d and the gate conductive layer 221m over the gate dielectric layer 220d. The depletion gate 222 includes the gate dielectric layer 220d and the gate conductive layer 222m over the gate dielectric layer 220d. The depletion gates 221 and 222 share the same gate dielectric layer 220d. In FIGS. 10A and 10B, the gate conductive layers 221m and 222m extend along the direction y and are separated from each other in the direction x. The source/drain regions 211 and 212 are between the depletion gates 221 and 222 in the direction x.

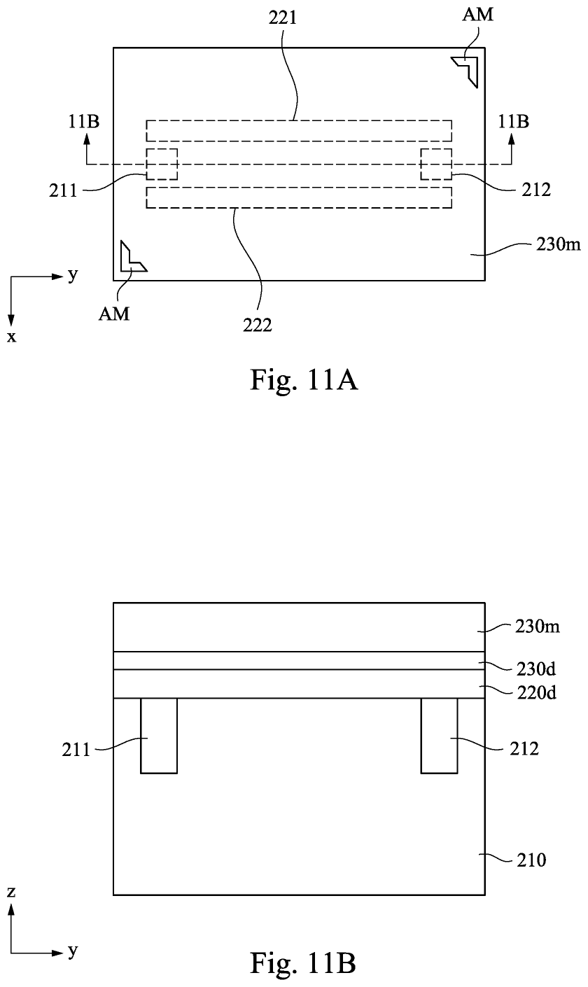

Reference is made to FIGS. 11A and 11B. FIG. 11A and 11B are a schematic top view and a schematic cross-section view illustrating depositing a layer stack of a gate dielectric layer 230d and a conductive layer 230m conformally over the gate dielectric layer 220d and the gate conductive layers 221m and 222m of the depletion gates 221 and 222 according to one or more embodiments of the present disclosure. It is noted that the source/drain regions (e.g., source/drain regions 211 and 212) the gate regions (e.g., depletion gates 221 and 222) covered by the gate dielectric layer 230d and the conductive layer 230m are presented as dash-lines in FIG. 11A.

As shown in FIGS. 11A and 11B, the gate dielectric layer 230d is conformally deposited over the depletion gates 221 and 222. In some embodiments of the present disclosure, the gate dielectric layer 230d may include Al₂O₃. The gate dielectric layer 230d is deposited by suitable techniques, such as ALD, CVD, PVD, thermal oxidation, combinations thereof, or other suitable techniques.

The conductive layer 230m is then deposited over the gate dielectric layer 230d. In some embodiments of the present disclosure, the conductive layer 230m may include one or more layers of conductive material, e.g., metal material. In one or more embodiments of the present disclosure, the metal layer 230m may be formed by chemical vapor deposition (CVD), physical vapor deposition (PVD) including sputtering, atomic layer deposition (ALD) or other suitable method.

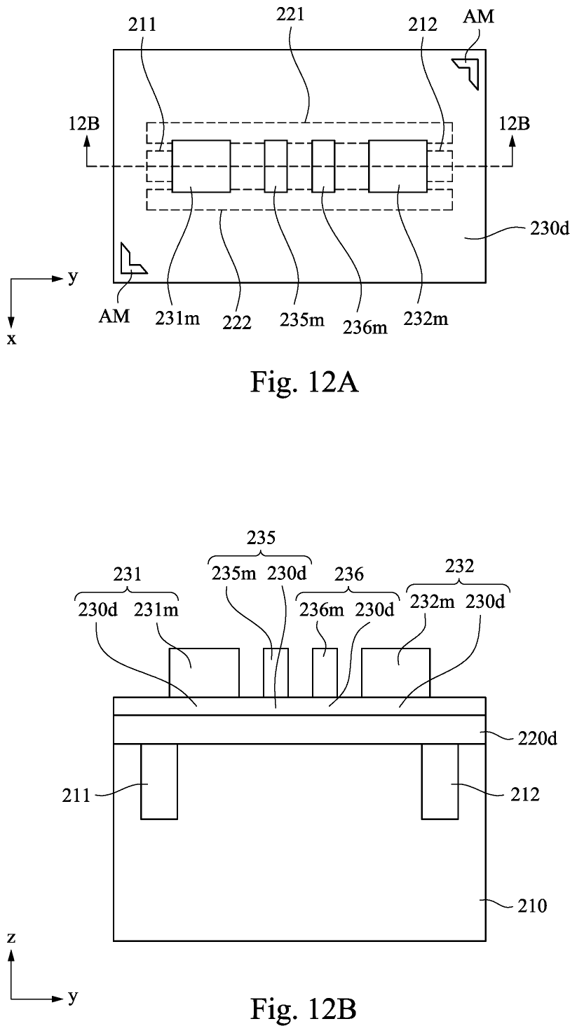

Reference is made to FIGS. 12A and 12B. FIG. 12A and 12B are a schematic top view and a schematic cross-section view illustrating formation of gate conductive layers 231m, 232m, 235m and 236m over the gate dielectric layer 230d according to one or more embodiments of the present disclosure.

As illustrated in FIGS. 12A and 12B, the conductive layer 230m in FIGS. 12A and 12B is patterned to form gate conductive layers 231m, 232m, 235m and 236m over the gate dielectric layer 230d, arranged along the direction x and separated from each other. In one or more embodiments of the present disclosure, the patterning of the conductive layer 230m may be formed using a combination of photolithography for definition of the gate conductive layers 231m, 232m, 235m and 236m and etching process, for example, RIE process, for forming the gate conductive layers 231m, 232m, 235m and 236m.

In FIGS. 12A and 12B, the extension gates 231, 232 and the accumulation gates 235, 236 are formed. The extension gate 231 includes the gate dielectric 230d and the gate conductive layer 231m. The extension gate 232 includes the gate dielectric 230d and the gate conductive layer 232m. Lengths of the gate conductive layers 231m and 232m of the extension gates 231, 232 are arbitrary as long as overlapping with the source/drain regions 211 and 212. The accumulation gate 235 includes the gate dielectric 230d and the gate conductive layer 235m. The accumulation gate 236 includes the gate dielectric 230d and the gate conductive layer 236m. The extension gates 231, 232 and the accumulation gates 235, 236 share the same gate dielectric layer 230d.

As shown in FIG. 12A and 12B, in one or more embodiments of the present disclosure, the formed gate conductive layers 231m, 232m, 235m and 236m of the extension gates 231, 232 and the accumulation gates 235, 236 overlap the depletion gates 221 and 222.

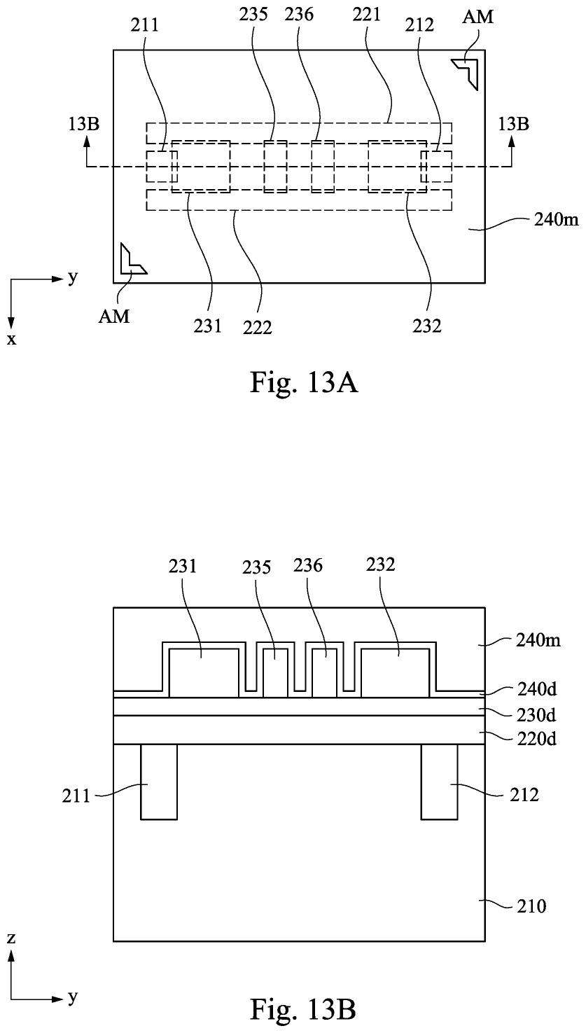

Reference is made to FIGS. 13A and 13B. FIGS. 13A and 13B are a schematic top view and a schematic cross-section view illustrating depositing a layer stack of a gate dielectric layer 240d and a conductive layer 240m over the extension gates 231, 232 and the accumulation gates 235, 236 according to one or more embodiments of the present disclosure.

As illustrated in FIGS. 13A and 13B, the gate dielectric layer 240d is conformally deposited over the gate dielectric layer 230d and the gate conductive layers 231m, 232m, 235m and 236m of the extension gates 231, 232 and the accumulation gates 235, 236. The conductive layer 240m is deposited over the gate dielectric layer 240d.

In some embodiments of the present disclosure, the gate dielectric layer 240d may include Al₂O₃. In one or more embodiments of the present disclosure. The gate dielectric layer 240d is deposited by suitable techniques, such as ALD, CVD, PVD, thermal oxidation, combinations thereof, or other suitable techniques.

The conductive layer 240m is then deposited over the gate dielectric layer 240d. In some embodiments of the present disclosure, the conductive layer 230m may include one or more layers of conductive material, e.g., metal material. In one or more embodiments of the present disclosure, the metal layer 230m may be formed by chemical vapor deposition (CVD), physical vapor deposition (PVD) including sputtering, atomic layer deposition (ALD) or other suitable method.

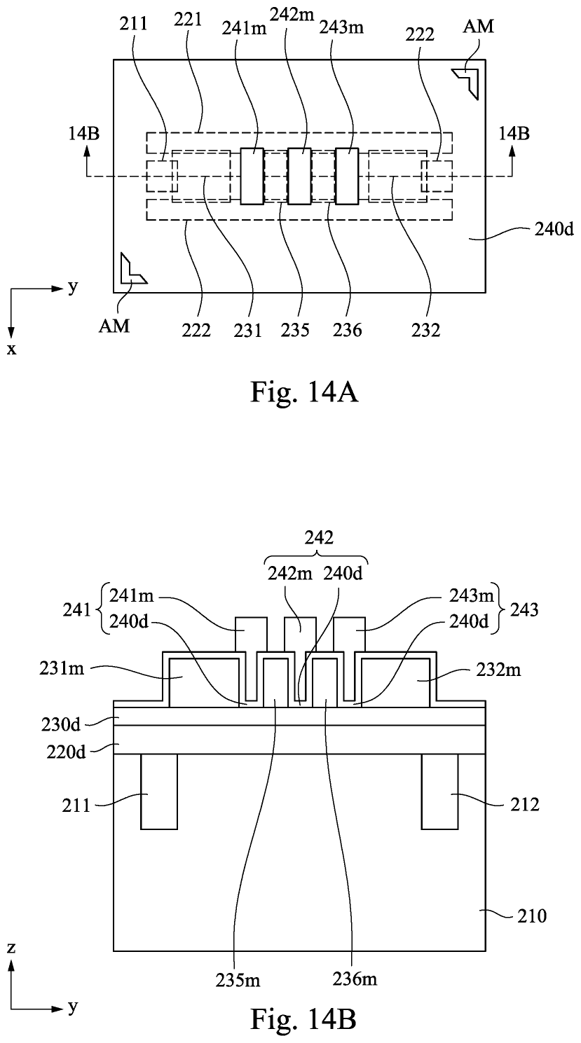

Reference is made to FIGS. 14A and 14B. FIG. 14A and 14B are a schematic top view and a schematic cross-section view illustrating formation of gate conductive layers 241m, 242m and 243m over the gate dielectric layer 240d according to one or more embodiments of the present disclosure.

As illustrated in FIGS. 14A and 14B, the conductive layer 240m in FIGS. 13A and 13B is patterned to form gate conductive layers 241m, 242m and 243m over the gate dielectric layer 240d. The gate conductive layers 241m, 242m and 243m are arranged along the direction x and separated from each other by the accumulation gates 235 and 236. In one or more embodiments of the present disclosure, the patterning of the conductive layer 240m may be formed using a combination of photolithography for definition of the gate conductive layers 241m, 242m and 243m and etching process, for example, RIE process, for forming the gate conductive layers 241m, 242m and 243m.

In FIGS. 14A and 14B, the barrier gates 241, 242 and 243 are formed over and between the accumulation gates 235 and 236. The barrier gate 241 includes the gate dielectric layer 240d and the gate conductive layer 241m over the gate dielectric layer 240d. The barrier gate 242 includes the gate dielectric layer 240d and the gate conductive layer 242m over the gate dielectric layer 240d. The barrier gates 241 and 242 share the same gate dielectric layer 240d.

As shown in FIGS. 14A and 14B, the barrier gate 243 includes the gate dielectric layer 240d and the gate conductive layer 243m over the gate dielectric layer 240d. The barrier gate 241 is between the extension gate 231 and the accumulation gate 235. The barrier gate 242 is between the accumulation gates 235 and 236. The barrier gate 243 is between the accumulation gate 236 and the extension gate 232. The barrier gates 241 and 242 forming a pair of the barrier gates are at two opposite sides of the accumulation gate 235 in the direction y, and the barrier gates 242 and 243 forming a pair of the barrier gates are at two opposite sides of the accumulation gate 236 in the direction y. The barrier gates 242 can be regarded as a common barrier gate for the accumulation gates 235 and 236.

In one or more embodiments of the present disclosure, the gate dielectric layers 220d, 230d and 240d may include silicon dioxide, silicon nitride, or other suitable material. Alternatively, the gate dielectric layer 220d, 230d and 240d can be a high-κ dielectric layer having a dielectric constant (κ) higher than the dielectric constant of SiO₂, i.e. κ>3.9. The gate dielectric layer 220d may include LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. The gate dielectric layer 220d, 230d and 240d is deposited by suitable techniques, such as ALD, CVD, PVD, thermal oxidation, combinations thereof, or other suitable techniques.

In one or more embodiments of the present disclosure, examples of the gate conductive layers 221m, 222m, 231m, 232m, 235m, 236m, 241m, 242m and 243m formed by the conductive layers 220m, 230m and 240m may include W, Ti, TiAIC, Al, TiAl, TaN, TaAlC, TiN, TiC, Co, TaC, Al, TiAl, HfTi, TiSi, TaSi, TiAlC, combinations thereof, or the like. The conductive layers 220m, 230m and 240m may be formed by chemical vapor deposition (CVD), physical vapor deposition (PVD) including sputtering, atomic layer deposition (ALD) or other suitable method.

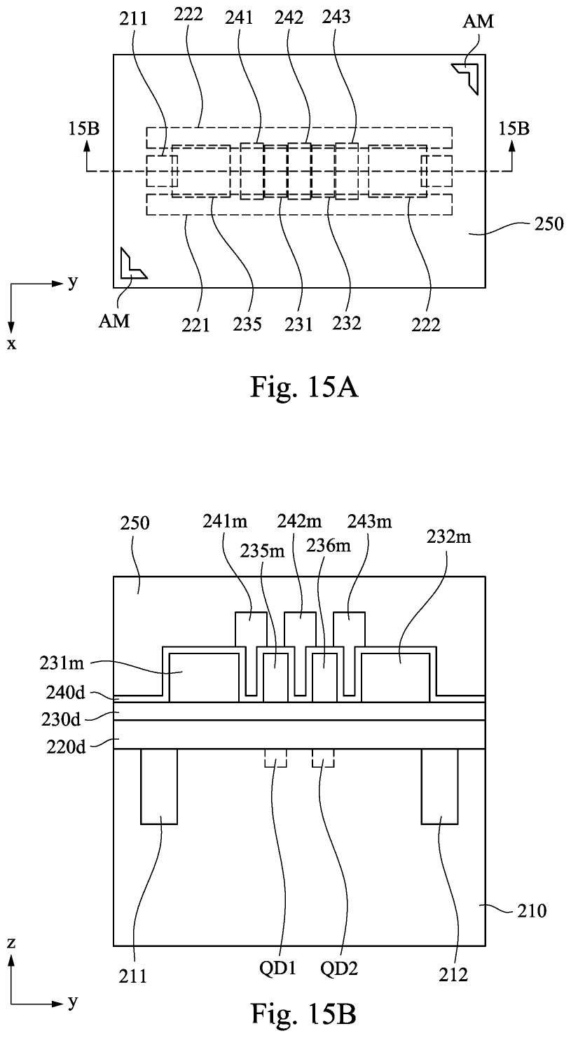

Reference is made to FIGS. 15A and 15B. FIGS. 15A and 15B are a schematic top view and a schematic cross-section view illustrating formation of an isolation dielectric layer 250 according to one or more embodiments of the present disclosure.

In one or more embodiments of the present disclosure, the formation of the isolation dielectric layer 250 can be a passivation oxide deposition process. As illustrated in FIGS. 15A and 15B, an isolation dielectric layer 250 is formed over the gate dielectric layer 230d and the gate conductive layers 231m, 232m, 235m, 236m of the extension gates 231, 232 and the accumulation gates 235, 236 and the gate dielectric layers 240d and the gate conductive layers 241m, 242m and 243m of the barrier gates 241, 242 and 243.

In one or more embodiments of the present disclosure, material of the isolation dielectric layer 250 may include SiO₂. In some embodiments of the present disclosure, the isolation dielectric layer 250 can be a high-κdielectric layer having a dielectric constant (κ) higher than the dielectric constant of SiO₂, i.e. κ>3.9. The isolation dielectric layer 250 may include LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. The isolation dielectric layer 250 is deposited by suitable techniques, such as ALD, CVD, PVD, thermal oxidation, combinations thereof, or other suitable techniques.

After the depletion gates 221, 222, the accumulation gates 235, 236 and the barrier gates 241, 242 and 243 are formed, quantum dot regions QD1 and QD2 can be defined under the accumulation gates 235, 236 in the substrate 210. Two carriers transported from the source/drain region 211 or 212 can be respectively bound in the quantum dot regions QD1 and QD2. The two carriers may be, for example, two electrons or two holes. The depletion gates 221, 222 and the barrier gates 241, 242 and 243 can the regarded as energy barriers for the two carriers. The accumulation gates 235, 236 are configured to provide two separated energy grounds for the two carriers. By adjusting the voltage applied to the barrier gates 241, 242 and 243, the two carriers can be controlled and bound in the quantum dot regions QD1 and QD2. Each of the quantum dot regions QD1 and QD2 may store one of the two carriers.

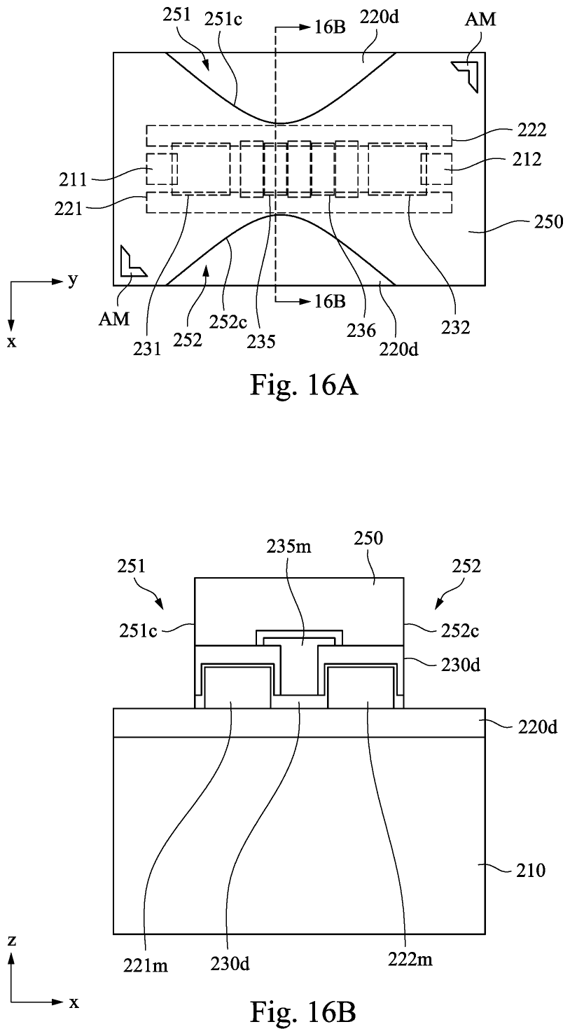

Reference is made to FIG. 16A and FIG. 16B. FIGS. 16A and 16B are a schematic top view and a schematic cross-section view illustrating etching the isolation dielectric layer 250 to form a pair of magnet trenches 251 and 252 separated from each other in direction x according to one or more embodiments of the present disclosure.

As shown in FIGS. 16A and 16B, the magnet trenches 251 and 252 extend through the isolation dielectric layer 250 and the gate dielectric layers 240d and 230d to the top surface of the gate dielectric layer 220d. The magnet trenches 251 and 252 are not overlap with the gate conductive layers 221m and 222m of the depletion gates 221 and 222 and do not expose the gate conductive layers 231m, 232m, 235m, 236m, 241m, 242m and 243m over the gate conductive layers 221m and 222m.

In some embodiments of the present disclosure, the magnet trenches 251 and 252 are formed using a combination of photolithography for defining the magnet trenches 251 and 252 and etching process (e.g., RIE process) for etching the isolation dielectric layer to form the defined magnet trenches 251 and 252.

As illustrated in FIGS. 16A and 16B, in one or more embodiments of the present disclosure, the magnet trench 251 includes a concave surface 251c and the magnet trench 252 includes a concave surface 252c. The depletion gates 221 and 222 are between the concave surfaces 251c and 252c. In one or more embodiments of the present disclosure, the concave surfaces 251c and 252c form a hyperbola in the schematic top view of FIG. 16A.

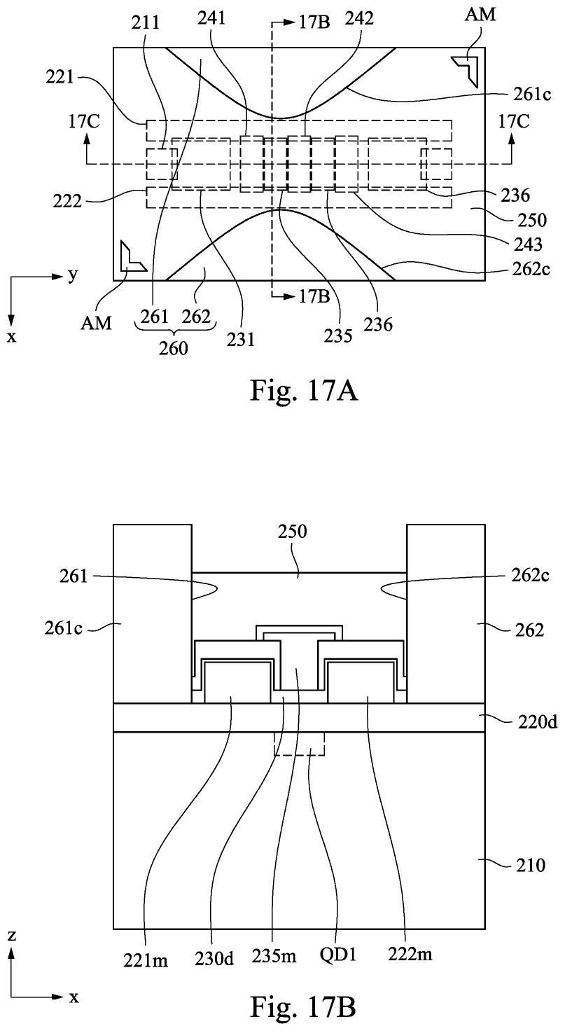

Reference is made to FIG. 17A and FIG. 17B. FIGS. 17A and 17B are a schematic top view and a schematic cross-section view illustrating formation of a hyperbolic magnet 260 including a pair of magnet portions 261 and 262.

Magnetic material is deposited in magnet trenches 251 and 252 to form the magnet portion 261 and the magnet portion 262 having a convex surface 262c facing a convex surface 261c of the magnet portion 261. In one or more embodiments of the present disclosure, the hyperbolic magnet 260 is formed using a combination of deposition a ferromagnetic metal layer filled with the magnet trenches 251 and 252, photolithography for the ferromagnetic metal layer to define the magnet portions 261 and 262 and etching process (e.g., RIE process) for etching the ferromagnetic metal layer to form the defined magnet portions 261 and 262.

For example, in some embodiments of the present disclosure, a ferromagnetic metal layer is formed over the isolation dielectric layer 250 and fills the magnet trenches 251 and 252. In some embodiments of the present disclosure, the ferromagnetic metal layer may be formed by chemical vapor deposition (CVD), physical vapor deposition (PVD) including sputtering, atomic layer deposition (ALD) or other suitable method. A mask layer is then formed over the ferromagnetic metal layer and is patterned to define the magnet portions 261 and 262. Based on the patterned mask layer over the ferromagnetic metal layer, the magnet portions 261 and 262 are formed and respective have convex surfaces 261c and 262c complementary to the concave surfaces 251c and 252c. The patterned mask layer used to define the magnet portions 261 and 262 is removed after the magnet portions 261 and 262 are formed.

In the schematic top view as illustrated in FIG. 17A, the convex surfaces 261c and 262c of the magnet portions 261 and 262 form a hyperbola profile. The convex surface 261c is symmetric to the convex surface 262c. As shown in FIG. 17B, bottom surface of the magnet portions 261 and 262 are lower than top surface of the depletion gates 221 and 222, and top surfaces of the magnet portions 261 and 262 are higher than a top surface of the isolation dielectric layer 250. The depletion gates 221 and 221 and structures over the depletion gates 221 and 222 are between the magnet portions 261 and 262. The isolation dielectric layer 250 is directly connected between the convex surfaces 261c and 262c of the magnet portions 261 and 262.

In one or more embodiments of the present disclosure, the bottom surfaces of the magnet portions 261 and 262 are lower top surfaces of the accumulation gates 235 and 236. The bottom surfaces of the magnet portions 261 and 262 are level with the top surface of the gate dielectric layer 220d and bottom surfaces of the gate dielectric layer 135d and the gate conductive layers 221m and 222m. The bottom surfaces of the magnet portions 261 and 262 are lower than a bottom surface of the gate dielectric layer 230d and the isolation dielectric layer 250.

The magnet portions 261 and 262 next to depletion gates 221 and 222 and having the convex surfaces 261c and 262c are utilized for inducing magnetic field with large gradient along the direction x. In one or more embodiments, as examples but not limit to the present disclosure, once the two carriers are bound in the quantum dot regions QD1 and QD2, the two carriers can sense magnetic field generated by the pair of magnet portions 261 and 262 of the hyperbolic magnet 260, and the degenerated electron/hole spin eigenstates (e.g., spin-up and spin-down state) for the two carrier split and have different energies.

It is noted the energy splitting of the two carriers in the two different quantum dot regions QD1 and QD2 are different since a distance between the convex surfaces 261c and 262c across the accumulation gate 235 over the quantum dot region QD1 is different from a distance between the convex surfaces 261c and 262c across the accumulation gate 236 over the quantum dot region QD2 in direction x. Accordingly, spin quantum states of the two carriers in the different quantum dot regions QD1 and QD2 are distinguishable and may be regarded as two spin qubits. The two spin qubits can be independently controlled by applying AC voltage difference with different frequencies matching the Rabi frequencies of the spin qubits to the depletion gates 221 and 222.

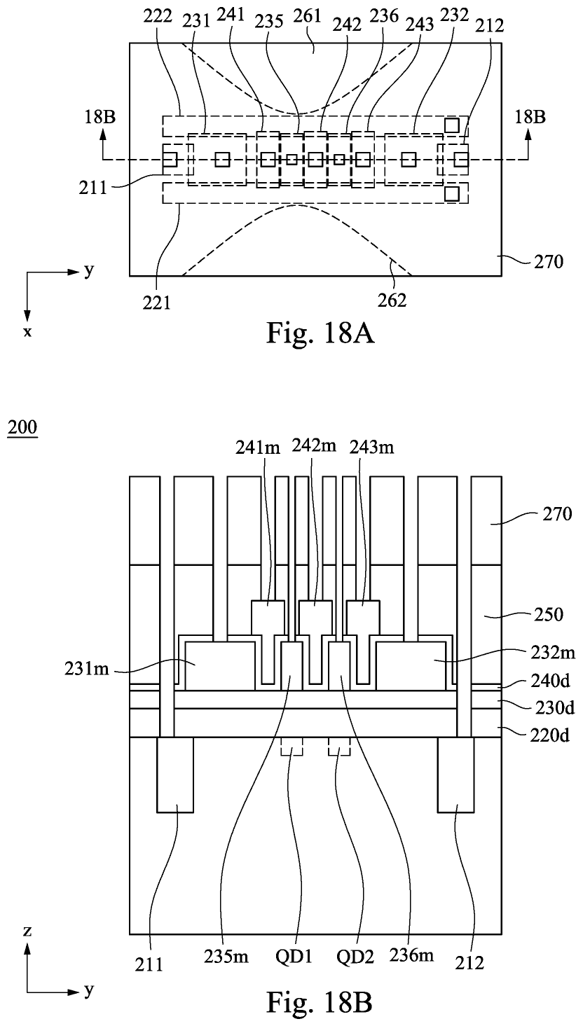

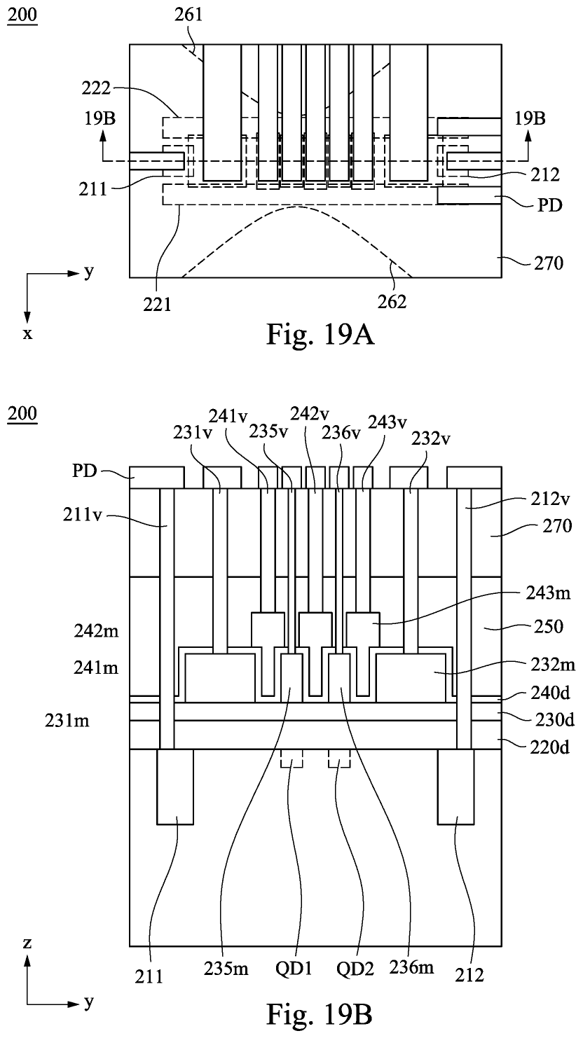

Reference is made to FIGS. 18A, 18B and FIGS. 19A and 19B. FIGS. 18A-19B are schematic top views and schematic cross-section views illustrating formation of vias and contact metal pads connected to the plurality of gates and providing the electronic device 200 of the present disclosure.

FIGS. 18A and 18B illustrate formation of an isolation dielectric layer 270 over the isolation dielectric layer 250 and the hyperbolic magnets 260 including the magnet portions 261 and 262. In some embodiments of the present disclosure, material of the isolation dielectric layer 270 may be the same as the material of the isolation dielectric layer 250 and deposited over the isolation dielectric layer 250 and the hyperbolic magnets 260 by similar deposition process. A plurality of vias aligned with the source/drain regions 211, 212, the depletion gates 221, 222, the extension gates 231, 232, the accumulation gates 235, 236 and the barrier gates 241, 242 and 243 are defined using a combination of photolithography and etching process (e.g., RIE process). FIGS. 19A and 19B illustrates formations of the vias 211v, 212v, 221v, 222v, 231v, 232v, 235v, 236v, 241v, 242v, 243v aligned with the source/drain regions 211, 212, the depletion gates 221, 222, the extension gates 231, 232, the accumulation gates 235, 236 and the barrier gates 241, 242 and 243.

In one or more embodiments of the present disclosure, the vias 211v, 212v extend through the isolation dielectric layers 250, 270 and the gate dielectric layers 240d, 230d and 220d to the source/drain regions 211 and 212. The vias 221v, 222v extend through the isolation dielectric layers 250, 270 and the gate dielectric layers 240d and 230d to the gate conductive layers 221m and 222m of the depletion gates 221 and 222. The vias 231v, 232v extend through the isolation dielectric layers 250, 270 and the gate dielectric layer 240d to the gate conductive layers 231m and 232m of the extension gates 221 and 222. The vias 235v, 236v extend through the isolation dielectric layers 250, 270 and the gate dielectric layer 240d to the gate conductive layers 235m and 236m of the accumulation gates 235 and 236. The vias 241v, 242v and 243v extend through the isolation dielectric layers 250 and 270 to the gate conductive layers 241m, 242m and 243m of the barrier gates 241, 242 and 243.

In one or more embodiments of the present disclosure, the vias 211v, 212v, 221v, 222v, 231v, 232v, 235v, 236v, 241v, 242v, 243v may include W, Ti, TiAIC, Al, TiAl, TaN, TaAIC, TIN, TIC, Co, TaC, Al, TiAl, HfTi, TiSi, TaSi, TiAIC, combinations thereof, or the like. The vias 211v, 212v, 221v, 222v, 231v, 232v, 235v, 236v, 241v, 242v, 243v may be formed by chemical vapor deposition (CVD), physical vapor deposition (PVD) including sputtering, atomic layer deposition (ALD) or other suitable method. In some embodiments, a mask layer is formed above the isolation dielectric layer 270 to protect the isolation dielectric layer 270 prior to forming the vias 211v, 212v, 221v, 222v, 231v, 232v, 235v, 236v, 241v, 242v, 243v, and the mask layer is removed after the formation of the vias 211v, 212v, 221v, 222v, 231v, 232v, 235v, 236v, 241v, 242v, 243v.

After the vias 211v, 212v, 221v, 222v, 231v, 232v, 235v, 236v, 241v, 242v, 243v are formed, a metal layer is formed and patterned over the isolation dielectric layer 270 to define a plurality of contact metal pads PD connected to the vias 211v, 212v, 221v, 222v, 231v, 232v, 235v, 236v, 241v, 242v, 243v. In one or more embodiments of the present disclosure, the contact metal pads PD are formed using a combination of photolithography, sputter and lift-off process.

In one or more embodiments of the present disclosure, material of the vias 211v, 212v, 221v, 222v, 231v, 232v, 235v, 236v, 241v, 242v, 243v and the metal pads PD may include copper, gold or other suitable material.

In one or more embodiments of the present disclosure, after the metal pads PD, a oxide layer used for top oxide cladding may be formed over the metal pads PD and the isolation dielectric layer 270 by a PECVD process. For the sake of clarity, formation the oxide layer used for top oxide cladding is not illustrated in figures.

As shown in FIGS. 19A and 19B, an electronic device 200 is formed and includes the substrate 210, the depletion gates 221 and 222 over the substrate 210, the extension gates 231, 232 and the accumulation gates 235, 236 over the depletion gates 221, 222, the barrier gates 241, 242 and 243 over the extension gates 231, 232 and the accumulation gates 235, 236 and the hyperbolic magnets 260 including the magnet portions 261 and 262 separated from each other by at least the depletion gates 221 and 222. The electronic device 200 includes the isolation dielectric layer 250 over the barrier gates 241, 242 and 243. The electronic device 200 includes the isolation dielectric layer 270 over the isolation dielectric layer 270 over the isolation dielectric layer 250 and the magnet portions 261 and 262. The electronic device 200 includes the vias 211v, 212v, 221v, 222v, 231v, 232v, 235v, 236v, 241v, 242v, 243v extending to the source/drain regions 211, 212 of the substrate 210, the depletion gates 221, 222, the extension gates 231, 232, the accumulation gates 235, 236 and the barrier gates 241. 242 and 243. The electronic device 200 includes the metal pads PD connected to the vias 211v, 212v, 221v, 222v, 231v, 232v, 235v, 236v, 241v, 242v, 243v.

In one or more embodiments of the present disclosure, different DC voltages may be applied to the source/drain regions 211, 212 of the substrate 210, the depletion gates 221, 222, the extension gates 231, 232, the accumulation gates 235, 236 and the barrier gates 241, 242 and 243 through the metal pads PD to bind two carriers in the quantum dot regions QD1 and QD2 in the substrate 210 under the accumulation gates 235 and 236. An AC voltage difference may be further induced for the depletion gates 221 and 222 such that the two distinguishable carriers bound in the quantum dot regions QD1 and QD2 effectively sense oscillation magnetic field under the magnetic field generated by the magnet portions 261 and 262 and having large gradient along the direction x.

In FIGS. 19A and 19B, two accumulation gates 235 and 236 are between the convex surfaces 261c and 262c of the magnet portions 261 and 262. In one or more embodiments, one or more numbers of accumulation gates and barrier gates can be provided between the convex surfaces 261c and 262c to induce one or more quantum dot regions to bind carriers and define distinguishable spin qubits.

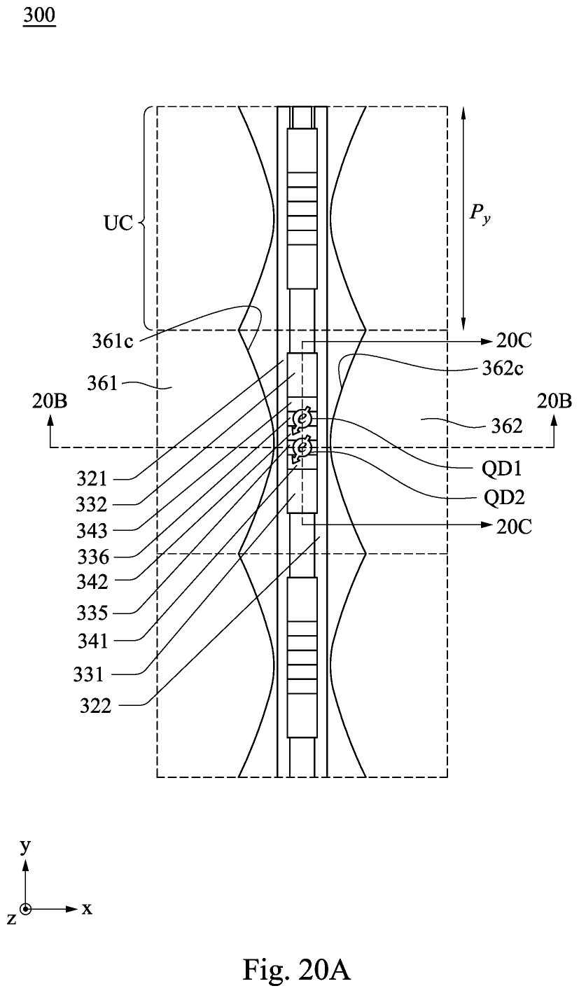

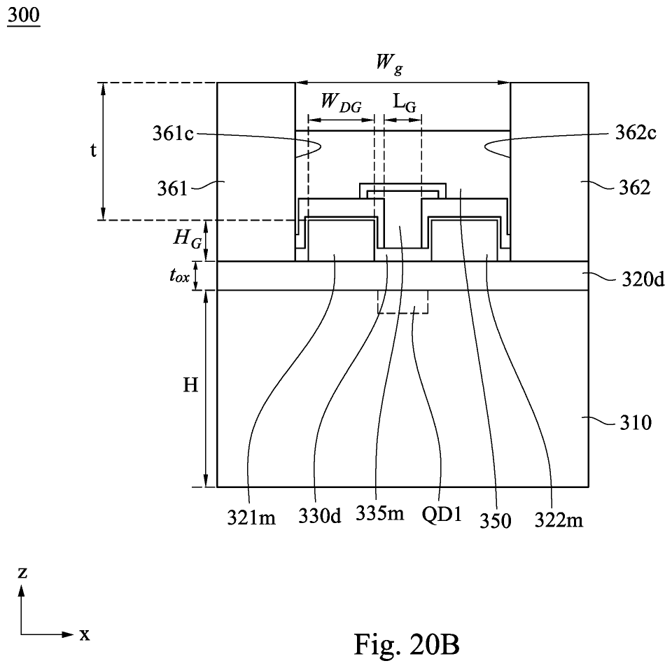

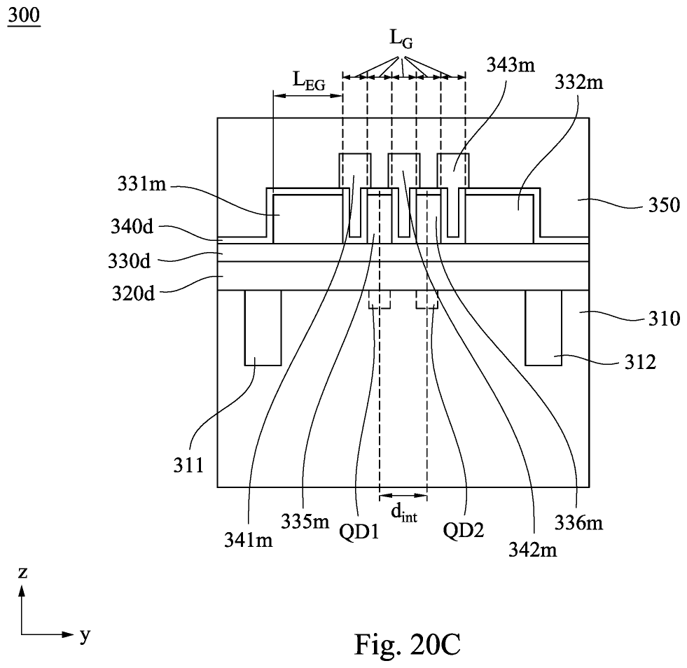

FIG. 20A, 20B and 20C illustrates a schematic top view and schematic cross-section view of an electronic device 300 according to one or more embodiments of the present disclosure. For the sake of clarity, one or more dielectric layers, vias and contact pad are not illustrated in FIG. 20A.

As illustrated in FIG. 20A, the electronic device 300 includes a plurality of unit cells UC arranged in the direction y periodically.

In FIGS. 20A, 20B and 20C, each unit cell UC includes a substrate 310 having source/drain regions 311 and 312, a pair of depletion gates 321, 322 over the substrate 310, extension gates 331, 332 and accumulation gates 335, 336 over the depletion gates 321, 322 and barrier gates 341, 342 and 343 over the extension gates 331, 332 and the accumulation gates 335. Each unit cell UC includes a hyperbolic magnet 360 including magnet portions 361, 362 separated by at least the depletion gates 321 and 322. The depletion gates 321, 322 are between the convex surface 361c and 362c of the magnet portions 361 and 362. As shown in FIG. 20A, in one or more embodiments of the present disclosure, the depletion gates 321 and 322 extend across the unit cells UC in direction y. The spin qubits of the unit cells UC share the same the depletion gates 321 and 322. Quantum dot regions QD1 and QD2 are induced in the substrate 310 under the accumulation gates 335 and 336. Each of the quantum dot regions QD1 and QD2 is configured to bind a single carrier (e.g., electron or hole) to form a spin qubit.

In one or more embodiments of the present disclosure, a periodic length Py of the unit cells UC is equal to or less than 800 nm. It is noted that the periodic length Py can be regarded as a cut-off length of a hyperbola formed by the convex surface 361c and 362c, and a magnitude of the magnetic field generated by the hyperbolic magnet 360 at boundaries of the unit cells UC may be determined by the periodic length Py.

FIG. 20B illustrates a schematic cross-section view along the direction x to illustrated the depletion gates 321, 322 and the accumulation gate 335. The depletion gate 321 includes a gate dielectric layer 320d and a gate conductive layer 321m over the gate dielectric layer 320d. The depletion gate includes the gate dielectric layer 320d and a gate conductive layer 322m. The accumulation gate 335 includes a gate dielectric layer 330d over the depletion gates 321, 322 and a gate conductive layer 335m over the gate dielectric layer 330d.

As shown in FIG. 20B, in the direction z, the substrate 310 has a thickness H. each of the gate conductive layer 321m and 322m has a thickness H_{c}, the gate dielectric layer 320d has a thickness tₒₓ and each of the magnet portions 361 and 362 has a thickness t. In one or more embodiments of the present disclosure, the thickness H is equal to or greater than 500 μm, the thickness He is equal to or less than 50 nm, the thickness tₒₓ is equal to or less than 20 nm, and the thickness t is equal to or greater than 250 nm. In one or more embodiments of the present disclosure, thickness of each of the gate dielectric layers 330d and 340d has a thickness equal to or less than 20 nm in the direction z. In one or more embodiments of the present disclosure, a distance between top surfaces of the barrier gates 341, 342 and 343 and a top surface of the isolation dielectric layer 350 is equal to or less than 20 nm.

Reference is made to FIG. 20B. In direction x, a distance W_{g} is between the convex surfaces 361c and 362c of the magnet portions 361 and 362, each of the gate conductive layers 321m and 322m has a width W_{DG}, and the gate conductive layer 335m of the accumulation gate 335 between the gate conductive layers 321m and 322m of the depletion gates 321 and 322 has a length L_{G}. In one or more embodiments of the present disclosure, the length L_{G} is equal to or less than 50 nm, the distance W_{g} is in a range of 4 times of the length L_{G} to 400 nm, the width W_{DG} is equal to or less than 50 nm. It is noted that the length L_{G} can be regarded as sizes of the quantum dot regions QD1 and QD2 under the accumulation gates 335 and 336.

FIG. 20C illustrates a schematic cross-section view along the direction y to illustrate the extension gates 331, 332, the accumulation gates 335, 336 and the barrier gates 341, 342 and 343. The substrate 310 has source/drain regions 311 and 312. The extension gate 331 overlaps the source/drain region 311 and includes a gate dielectric layer 330d and a gate conductive layer 331m over the gate dielectric layer. The extension gate 332 overlaps the source/drain region 312 and includes the gate dielectric layer 330d and a gate conductive layer 332m over the gate dielectric layer. The accumulation gates 335 and 336 are between the extension gates 331 and 332. The accumulation gate 335 includes the gate dielectric layer 330d and a gate conductive layer 335m over the gate dielectric layer 330d. The accumulation gate 336 includes the gate dielectric layer 330d and a gate conductive layer 336m over the gate dielectric layer 330d. The barrier gates 341, 342 and 343 are over the extension gates 331, 332 and the accumulation gates 335 and 336. The barrier gate 341 includes a gate dielectric layer 340d and a gate conductive layer 341m over the gate dielectric layer 340d. The barrier gate 342 includes the gate dielectric layer 340d and a gate conductive layer 342m over the gate dielectric layer 340d. The barrier gate 343 includes the gate dielectric layer 340d and a gate conductive layer 343m over the gate dielectric layer 340d. The isolation dielectric layer 350 is over the barrier gates 341, 342 and 343.

As shown in FIG. 20C, in the direction y, the length LG is between immediately-adjacent two of the gate conductive layers 331m, 332m, 335m and 336m or is a width of each of the gate conductive layers 335m and 336m, each of the gate conductive layers 331m and 332m of the extension gates 331 and 332 has a length LEG, and a distance dint is between centers of the quantum dot regions QD1 and QD2 (i.e., a distance between centers of the gate conductive layers 335m and 336m of the accumulation gates 335 and 336). The distance dint is two times of the length LG. In one or more embodiments of the present disclosure, the length LEG is arbitrary as long as overlapping with a corresponding one of the source/drain regions 311 and 312.

In FIGS. 20A, 20B and 20C, the electronic device 300 has arrays of the quantum dot regions, and the electronic device 300 may be integrated in a large-scale qubit system having a plurality of spin qubits.

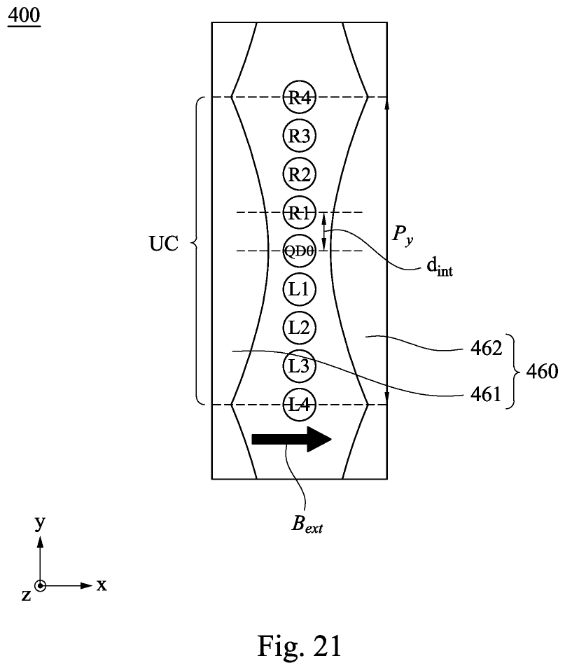

FIG. 21 illustrates a schematic top view of an electronic device 400 according to one or more embodiments of the present disclosure. The electronic device 400 has a one-dimensional qubit array in the direction y. Differences between the electronic device 300 and the electronic device 400 of FIG. 21 include that in the embodiments as illustrated in FIG. 21, the electronic device 400 includes more quantum dot regions QD0, L1, L2, L3, L4, R1, R2, R3 and R4 between magnet portions 461 and 462 of a hyperbolic magnet 460. FIG. 21 schematic illustrates the quantum dot regions QD0, L1, L2, L3, L4, R1, R2, R3 and R4 and the hyperbolic magnet 460, and substrates, a plurality of gates and isolation dielectric layers are not illustrated in FIG. 21 for the sake of clarity.

It is noted each of the quantum dot regions QD0, L1, L2, L3, L4, R1, R2, R3 and R4 is a region of the substrate closed by a pair of depletion gates, a pair of barrier gates and under an accumulation gate. As shown in FIG. 21, a distance dint is between centers of immediately-adjacent two of the quantum dot regions QD0, L1, L2, L3, L4, R1, R2, R3 and R4 in the direction y. In one or more embodiments of the present disclosure, each of the quantum dot regions QD0, L1, L2, L3, L4, R1, R2, R3 and R4 has a size equal to or less than 50 nm, and the distance dint is equal to or less than 100 nm, which is two times of 50 nm.

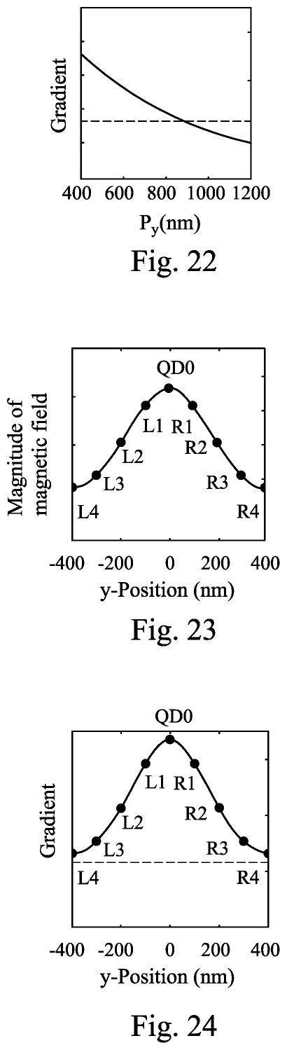

FIGS. 22-24 illustrate diagrams used for design the electronic device 400 of FIG. 21 according to one or more embodiments of the present disclosure.

Reference is made to FIGS. 21 and 22. FIG. 22 illustrates a diagram of relations between different period lengths Py and the gradient of the magnetic field generated by the magnet portions 461 and 462 of the hyperbolic magnet 460 at the boundary of the unit cell UC. The horizontal axis of FIG. 22 presents the different period lengths Py. The vertical axis of FIG. 22 presents the gradient of the magnetic field generated by the magnet portions 461 and 462 of the hyperbolic magnet 460 at the boundary of the unit cell UC. The period length Py can also be regarded as the y-directional truncated length to determine the shape of the hyperbolic magnet 460 in each unit cell UC.

As shown in FIG. 22, once the period length Py increases, a distance between the magnet portions 461 and 462 at the boundary of the unit cell UC increases and the gradient of the magnetic field at the boundary of the unit cell UC decreases. The gradient of the magnetic field would affect the Rabi frequency for flip the spin state in the spin qubit. In one or more embodiments of the present disclosure, in order to avoid slow control of the spin qubit (such as quantum dot regions R4 and L4) at the boundary caused by too small Rabi frequency, the period length Py is selected to be less than or equal to 800 nm to ensure that the gradient of the magnetic field at the boundary of the unit cell UC has enough value. A choice of the period length Py equal to or less than 800 nm is to maintain that Rabi frequency of each of spin qubits, which are provided by the quantum dot regions QD0, L1, L2, L3, L4, R1, R2, R3 and R4 in the unit cells UC, is greater than 25 MHz.

Reference is made to FIGS. 21 and 23. FIG. 23 illustrates a diagram of relations between the different quantum dot regions QD0, L1, L2, L3, L4. R1, R2, R3 and R4 at different positions in the direction y and the magnitude of the magnetic field generated by the magnet portions 461 and 462 of the hyperbolic magnet 460. The horizontal axis of FIG. 23 presents different positions in the direction y, wherein the original point is set at the position of the quantum dot region QD0. The vertical axis of FIG. 23 presents the magnitude of the magnetic field generated by the magnet portions 461 and 462.

As shown in FIG. 23, when the position of the quantum dot regions is closer to the boundary, the magnitude of the magnetic field sensed by the quantum dot regions becomes smaller. Different magnitudes of the magnetic fields make the degenerated spin states of different quantum dot regions QD0, L1, L2, L3, L4, R1, R2, R3 and R4 have different energy splitting, so as to be used for multiple distinguishable spin qubits. In one or more embodiments of the present disclosure, different magnitudes of magnetic fields would cause different spin qubits to have different Larmor frequencies. In one or more embodiments of the present disclosure, the multiple Larmor frequencies of quantum dot regions QD0, L1, L2, L3, L4, R1, R2, R3 and R4 in the unit cell UC are in a range of 26 to 32 GHz. In some embodiments of the present disclosure, with five qubits group, the bandwidth can reach 1.5 GHz per qubit. In some embodiments of the present disclosure, with five qubits group, the bandwidth can be in the range of 0.8 GHZ per qubit to 2.2 GHz per qubit.

Reference is made to FIGS. 21 and 24. FIG. 24 illustrates a diagram of relations between the different quantum dot regions QD0, L1, L2, L3, L4, R1, R2, R3 and R4 at different positions in the direction y and the gradient of the magnetic field generated by the magnet portions 461 and 462 of the hyperbolic magnet 460, wherein the periodic length Py is selected as 800 nm. The horizontal axis of FIG. 24 presents different positions in the direction y, wherein the original point is set at the position of the quantum dot region QD0. The vertical axis of FIG. 24 presents the gradient of the z-direction magnetic field generated by the magnet portions 461 and 462 along the direction x at different positions in the direction y.

Similar to the trend in FIG. 23, as the position of the quantum dot regions QD0, L1, L2, L3, L4, R1, R2, R3 and R4 is closer to the boundary, the gradient of the magnetic field sensed by the quantum dot regions QD0, L1, L2, L3, L4, R1, R2, R3 and R4 becomes smaller. In one or more embodiments of the present disclosure, different magnetic field gradients would cause that different spin qubits, which are provided by the quantum dot regions QD0, L1, L2, L3, L4, R1, R2, R3 and R4 in the unit cells UC, to have different Rabi frequencies. In one or more embodiments of the present disclosure, the gradient of the z-direction magnetic field generated by the magnet portions 461 and 462 along the direction x at different positions in the direction y is in a range of 1.9 mT/nm to 4.8 mT/nm, and the Rabi frequency of each of the spin qubits in the unit cell UC is in a range of 27 MHz to 67 MHZ.

Therefore, for the electronic device 400 as illustrated in FIG. 21, based on FIGS. 22-24, a design rule of the unit cells UC including a plurality of quantum dot regions and a hyperbolic magnet can be determined. The periodic length Py and the positions of the quantum dot regions can be selected so as to ensure spin addressability and operation speeds of spin qubits for a large-scale spin qubit system.

According to one or more embodiments of the present disclosure, an electronic device includes a substrate, a first hyperbolic magnet, a pair of first depletion gates, a pair of first barrier gate and a first accumulation gate. The first hyperbolic magnet is over the substrate and has a first magnet portion and a second magnet portion separated from each other. The first magnet portion has a first convex surface. The second magnet portion has a second convex surface facing the first convex surface. The first depletion gates are separated from each other and between the first convex surface of the first magnet portion and the second convex surface of the second magnet portion. The first barrier gates between the first depletion gates. The first accumulation gate is over the first depletion gates and between the first barrier gates. In one or more embodiments of the present disclosure, the electronic device further includes source/drain regions in the substrate and at opposite sides of the first accumulation gate and an extension gate between the first depletion gates, wherein the extension gate overlaps one of the source/drain regions. In one or more embodiments of the present disclosure, the first depletion gates includes a gate dielectric layer and a gate conductive layer over the gate dielectric layer, wherein bottom surfaces of the first magnet portion and the second magnet portion of the first hyperbolic magnet are level with a bottom surface of the gate conductive layer. In one or more embodiments of the present disclosure, the first accumulation gate is between the first convex surface of the first magnet portion and the second convex surface of the second magnet portion. In one or more embodiments of the present disclosure, the electronic device further includes a second accumulation gate over the first depletion gates. One of the first barrier gates is between the first accumulation gate and the second accumulation gate. In one or more embodiments of the present disclosure, the electronic device further includes a second hyperbolic magnet, a pair of second depletion gates, a pair of second barrier gates and a second accumulation gate. The second hyperbolic magnet has a third magnet portion and a fourth magnet portion separated from each other. The third magnet portion has a third convex surface, and the fourth magnet portion has a fourth convex surface facing the third convex surface. The second depletion gates are between the third convex surface of the third magnet portion and the fourth convex surface of the fourth magnet portion. The second barrier gates are between the second depletion gates. The second accumulation gate is over the second depletion gates and between the second barrier gates. In some embodiments of the present disclosure, the second depletion gates are connected to the first depletion gates.

According to one or more embodiments of the present disclosure, an electronic device includes a substrate, a pair of depletion gates, a pair of extension gates, an accumulation gate, a pair of barrier gates, and a magnet. The substrate has a first source/drain region and a second source/drain region. The depletion gates are over the substrate and separated from each other. Each of the depletion gates comprises a first gate dielectric layer and a first gate conductive layer over the first gate dielectric layer. The extension gates overlap the first source/drain region and the second source/drain region, respectively. The accumulation gate is over the depletion gates and between the extension gates. The barrier gates are at opposite sides of the accumulation gate. The magnet has a first magnet portion and a second magnet portion separated from each other at least by the depletion gates. Bottom surfaces of the first magnet portion and the second magnet portion are lower than top surfaces of the depletion gates.

In one or more embodiments of the present disclosure, the bottom surfaces of the first magnet portion and the second magnet portion are level with top surfaces of the first gate dielectric layers of the depletion gates. In one or more embodiments of the present disclosure, the accumulation gate comprises a second gate dielectric layer and a second gate conductive layer over the second gate dielectric layer. The bottom surfaces of the first magnet portion and the second magnet portion are lower than a top surface of the second gate conductive layer of the accumulation gate. In one or more embodiments of the present disclosure, the barrier gates further comprise a second gate dielectric layer and a second gate conductive layer over the second gate dielectric layer. The bottom surfaces of the first magnet portion and the second magnet portion of the magnet are lower than second gate dielectric layer. In one or more embodiments of the present disclosure, the bottom surfaces of the first magnet portion and the second magnet portion are lower than a bottom surface of the accumulation gate. In one or more embodiments of the present disclosure, the electronic device further includes an isolation dielectric layer over the barrier gates and extending between the first magnet portion and the second magnet portion of the magnet. The bottom surfaces of the first magnet portion and the second magnet portion is lower than a bottom surface of the isolation dielectric layer. In one or more embodiments of the present disclosure, the first magnet portion has a first convex surface. The second magnet portion has a second convex surface, the first convex surface and the second convex surface form a hyperbola in a top view.

According to one or more embodiments of the present disclosure, a method includes a number of operations. The method includes forming a pair of depletion gates over a substrate; forming a first accumulation gate over the depletion gates; forming a pair of barrier gates at opposite sides of the first accumulation gate; forming an isolation dielectric layer over the barrier gates; forming a pair of trenches in the isolation dielectric layer, wherein the pair of trenches collectively form a hyperbolic profile from a top view; and depositing a magnetic material in the pair of trenches. In one or more embodiments of the present disclosure, the magnetic material in a first one of the pair of trenches has a first convex profile from the top view. In some embodiments of the present disclosure, the magnetic material in a second one of the pair of trenches has a second convex profile from the top view and the second convex profile is symmetric to the first convex profile. In one or more embodiments of the present disclosure, the method further includes forming a second accumulation gate separated from the first accumulation gate over the depletion gates. In one or more embodiments of the present disclosure, forming the pair of trenches comprises etching a dielectric layer of the first accumulation gate. In one or more embodiments of the present disclosure, the method further includes forming a pair of vias over the pair of the depletion gates.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic device comprising:
a substrate;
a first hyperbolic magnet over the substrate and having a first magnet portion and a second magnet portion separated from each other, wherein the first magnet portion has a first convex surface, and the second magnet portion has a second convex surface facing the first convex surface;
a pair of first depletion gates separated from each other and between the first convex surface of the first magnet portion and the second convex surface of the second magnet portion;
a pair of first barrier gates between the first depletion gates; and
a first accumulation gate over the first depletion gates and between the first barrier gates.

2. The electronic device of claim 1, further comprising:
source/drain regions in the substrate and at opposite sides of the first accumulation gate; and
an extension gate between the first depletion gates, wherein the extension gate overlaps one of the source/drain regions.

3. The electronic device of claim 1, wherein the first depletion gates comprise:
a gate dielectric layer; and
a gate conductive layer over the gate dielectric layer, wherein bottom surfaces of the first magnet portion and the second magnet portion of the first hyperbolic magnet are level with a bottom surface of the gate conductive layer.

4. The electronic device of claim 1, wherein the first accumulation gate is between the first convex surface of the first magnet portion and the second convex surface of the second magnet portion.

5. The electronic device of claim 1, further comprising:
a second accumulation gate over the first depletion gates, wherein one of the first barrier gates is between the first accumulation gate and the second accumulation gate.

6. The electronic device of claim 1, further comprising:
a second hyperbolic magnet having a third magnet portion and a fourth magnet portion separated from each other, wherein the third magnet portion has a third convex surface, and the fourth magnet portion has a fourth convex surface facing the third convex surface;
a pair of second depletion gates between the third convex surface of the third magnet portion and the fourth convex surface of the fourth magnet portion;
a pair of second barrier gates between the second depletion gates; and
a second accumulation gate over the second depletion gates and between the second barrier gates.

7. The electronic device of claim 6, wherein the second depletion gates are connected to the first depletion gates.

8. An electronic device comprising:
a substrate having a first source/drain region and a second source/drain region;
a pair of depletion gates over the substrate and separated from each other, wherein each of the depletion gates comprises a first gate dielectric layer and a first gate conductive layer over the first gate dielectric layer;
a pair of extension gates overlapping the first source/drain region and the second source/drain region, respectively;
an accumulation gate over the depletion gates and between the extension gates;
a pair of barrier gates at opposite sides of the accumulation gate; and
a magnet having a first magnet portion and a second magnet portion separated from each other at least by the depletion gates, wherein bottom surfaces of the first magnet portion and the second magnet portion are lower than top surfaces of the depletion gates.

9. The electronic device of claim 8, wherein the bottom surfaces of the first magnet portion and the second magnet portion are level with top surfaces of the first gate dielectric layers of the depletion gates.

10. The electronic device of claim 8, wherein the accumulation gate comprises a second gate dielectric layer and a second gate conductive layer over the second gate dielectric layer, and the bottom surfaces of the first magnet portion and the second magnet portion are lower than a top surface of the second gate conductive layer of the accumulation gate.

11. The electronic device of claim 8, wherein the barrier gates further comprise a second gate dielectric layer and a second gate conductive layer over the second gate dielectric layer, and the bottom surfaces of the first magnet portion and the second magnet portion of the magnet are lower than second gate dielectric layer.

12. The electronic device of claim 8, wherein the bottom surfaces of the first magnet portion and the second magnet portion are lower than a bottom surface of the accumulation gate.

13. The electronic device of claim 8, further comprising:
an isolation dielectric layer over the barrier gates and extending between the first magnet portion and the second magnet portion of the magnet, wherein the bottom surfaces of the first magnet portion and the second magnet portion is lower than a bottom surface of the isolation dielectric layer.

14. The electronic device of claim 8, wherein the first magnet portion has a first convex surface, the second magnet portion has a second convex surface, the first convex surface and the second convex surface form a hyperbola in a top view.

15. A method, comprising:
forming a pair of depletion gates over a substrate;
forming a first accumulation gate over the depletion gates;
forming a pair of barrier gates at opposite sides of the first accumulation gate;
forming an isolation dielectric layer over the barrier gates;
forming a pair of trenches in the isolation dielectric layer, wherein the pair of trenches collectively form a hyperbolic profile from a top view; and
depositing a magnetic material in the pair of trenches.

16. The method of claim 15, wherein the magnetic material in a first one of the pair of trenches has a first convex profile from the top view.

17. The method of claim 16, wherein the magnetic material in a second one of the pair of trenches has a second convex profile from the top view and the second convex profile is symmetric to the first convex profile.

18. The method of claim 15, further comprising:
forming a second accumulation gate separated from the first accumulation gate over the depletion gates.

19. The method of claim 15, wherein forming the pair of trenches comprises etching a dielectric layer of the first accumulation gate.

20. The method of claim 15, further comprising:
forming a pair of vias over the pair of the depletion gates.
